(19) United States
(12) Patent Application Publication
(10) Pub. No.: US 2025/0210934 A1
(43) Pub. Date: Jun. 26, 2025

(54) SEMICONDUCTOR LIGHT EMITTING DEVICE

(71) Applicant: SONY GROUP CORPORATION, TOKYO (JP)

(72) Inventors: SHOETSU NAGANE, TOKYO (JP); TATSUSHI HAMAGUCHI, TOKYO (JP); EIJI NAKAYAMA, TOKYO (JP); YUICHIRO KIKUCHI, TOKYO (JP); KENTARO HAYASHI, TOKYO (JP); JARED ALEXANDER KEARNS, TOKYO (JP)

(21) Appl. No.: 18/848,195

(22) PCT Filed: Mar. 15, 2023
(86) PCT No.: PCT/JP2023/010076

§ 371 Date: Sep. 18, 2024

(30) Foreign Application Priority Data
Mar. 25, 2022 (JP) 2022-049439

(51) Int. Cl. H01S 5/024; H01S 5/02257; H01S 5/42

(52) U.S. Cl. CPC H01S 5/02407; H01S 5/02257; H01S 5/423

(57) ABSTRACT

Deterioration of light emission characteristics due to heat is prevented. A semiconductor light emitting device includes: a light emitting unit; a sealing member that includes a transmission part that allows light emitted from the light emitting unit to transmit; and a heat control member that disperses heat of the light emitting unit using a cooling fluid inside of the sealing member.

### TECHNICAL FIELD

The present disclosure relates to a semiconductor light emitting device.

### BACKGROUND ART

A Vertical Cavity Surface Emitting Laser (VCSEL) that uses a nitride semiconductor can resonate light between two Distributed Bragg Reflectors (DBR) and emit planar light, and is used as a light source for various devices (see Patent Literature 1).

### CITATION LIST

### Patent Literature

### [PTL 1]

JP 2015-35543A.

### SUMMARY

### Technical Problem

Although the DRB has a multilayer structure formed by alternately laminating a layer of a high refractive index material and a layer of a low refractive index material, thermal conductivity of each layer that constitutes the DBR is low, and therefore it is concerned that heat is trapped inside of a resonator constituted by two DBRs, and original light emission characteristics cannot be obtained as designed.

Hence, the present disclosure provides a semiconductor light emitting device that can provide original light emission characteristics as designed.

### Solution to Problem

In order to solve the above problem, the present disclosure provides a semiconductor light emitting device that includes:

a light emitting unit;

a sealing member that includes a transmission part that allows light emitted from the light emitting unit to transmit; and

a heat control member that disperses heat of the light emitting unit using a cooling fluid inside of the sealing member.

The heat control member may cause the heat of the light emitting unit using the cooling fluid to convect between the light emitting unit and the sealing member.

The cooling fluid may be a gas, a liquid, or a solid that takes in the heat, and evaporates, melts, or sublimes.

The heat control member may include a first region that is disposed around the light emitting unit and has higher wettability than wettability of a front surface of the light emitting unit.

The heat control member may include a first region that is disposed around the light emitting unit, and has at least one of a surface tension and surface roughness different from a surface tension and surface roughness of a front surface of the light emitting unit.

The heat control member may include a second region that is disposed on the front surface of the light emitting unit, and has higher water repellency or oil repellency than water repellency or oil repellency of the first region.

The heat control member may include a plurality of protrusion parts provided on the front surface of the light emitting unit.

The heat control member may include

a first region that is disposed around the light emitting unit, and

a second region that is disposed on a front surface of the light emitting unit, and whose temperature becomes higher than a temperature of the first region at a time of light emission of the light emitting unit.

The second region may be disposed on a side closer to the transmission part than the first region, and

the heat control member may cause convection of the heat inside of the sealing member according to a temperature difference between the first region and the second region.

The light emitting unit may include a protrusion part that has an upper surface on which a light emission surface is disposed, and

the heat control member may include a roughened region that is disposed on at least part of a side surface of the protrusion part.

At least part of an inner surface of the sealing member may be a curved shape.

The semiconductor light emitting device may include a semiconductor chip that includes the light emitting unit,

the heat control member may include a plurality of grooves that are disposed on one major surface of the semiconductor chip,

each of the plurality of grooves may radially extend from the light emitting unit to an end part of the one major surface, and

widths of the plurality of grooves may be wider on a farther side than on a closer side to the light emitting unit.

The semiconductor light emitting device may include a semiconductor chip that includes the light emitting unit,

the heat control member may include a plurality of grooves that are disposed on one major surface of the semiconductor chip,

each of the plurality of grooves each having a different diameter may be disposed around the center of the light emitting unit so as to surround the light emitting unit, and

widths of the plurality of grooves may be wider on a farther side than on a closer side to the light emitting unit.

The light emitting unit may include a plurality of stacked layers, and

the heat control member may include a flow passage that is disposed in part of layers of the plurality of layers and through which the cooling fluid flows.

Thicknesses of the part of layers may be variably adjusted according to a pressure of the cooling fluid flowing in the flow passage,

the light emitting unit may include a resonator that resonates the light, and a resonator length of the light emitted from the light emitting unit may change according to the thicknesses of the part of layers.

The part of layers may include a current constriction region whose passing range of a current from an electrode of the light emitting unit is restricted by the flow passage.

The heat control member may include a light control member that covers at least part of the front surface of the light emitting unit, and includes a flow passage through which the cooling fluid flows.

The light control member may have a front surface shape that can collimate the light emitted from the light emitting unit and emit the light.

The semiconductor light emitting device may include a concave mirror that is disposed on a front surface of the light emitting unit, and

the light emitting unit may be a surface emitting laser that reflects light from an active layer by the concave mirror, or a vertical cavity surface emitting laser.

The semiconductor light emitting device may include an array part that includes a plurality of the light emitting units disposed in a one-dimensional or two-dimensional direction,

the sealing member may seal the array part and allow light emitted from each of the plurality of the light emitting units to transmit from the transmission part, and

the heat control member may disperse heat of the plurality of light emitting units using the cooling fluid inside of the sealing member.

### BRIEF DESCRIPTION OF DRAWINGS

FIG. 1A is a cross-sectional view illustrating a configuration of one embodiment of a semiconductor light emitting device to which the present technology is applied.

FIG. 1B is a plan view illustrating a configuration of a semiconductor chip in FIG. 1A.

FIG. 2A is an explanatory diagram of a relationship between wettability and a contact angle.

FIG. 2B is an explanatory diagram of the relationship between the wettability and the contact angle.

FIG. 2C is an explanatory diagram of the relationship between the wettability and the contact angle.

FIG. 2D is an explanatory diagram of the relationship between the wettability and the contact angle.

FIG. 3 is a cross-sectional view illustrating a configuration of a configuration of the semiconductor chip.

FIG. 4A is a cross-sectional view illustrating a configuration of a semiconductor light emitting device according to a second embodiment.

FIG. 4B is a plan view illustrating a configuration of a semiconductor chip in FIG. 4A.

FIG. 5A is a cross-sectional view illustrating a configuration of a semiconductor chip according to a third embodiment.

FIG. 5B is a plan view illustrating a configuration of a semiconductor light emitting device in FIG. 5A.

FIG. 6A is a cross-sectional view illustrating a configuration of a semiconductor chip according to a fourth embodiment.

FIG. 6B is a plan view illustrating a configuration of a semiconductor light emitting device in FIG. 6A.

FIG. 7A is a cross-sectional view illustrating a configuration of a semiconductor chip according to a fifth embodiment.

FIG. 7B is a plan view illustrating a configuration of a semiconductor light emitting device in FIG. 7A.

FIG. 8A is a cross-sectional view illustrating a configuration of a semiconductor chip according to a sixth embodiment.

FIG. 8B is a plan view illustrating a configuration of a semiconductor light emitting device in FIG. 8A.

FIG. 9A is a cross-sectional view illustrating a configuration of a semiconductor chip according to a seventh embodiment.

FIG. 9B is a plan view illustrating a configuration of a semiconductor light emitting device in FIG. 9A.

FIG. 10A is a cross-sectional view illustrating a configuration of a semiconductor light emitting device according to an eighth embodiment.

FIG. 10B is a plan view illustrating a configuration of a semiconductor chip in FIG. 10A.

FIG. 11A is a cross-sectional view illustrating a configuration of a semiconductor light emitting device according to a ninth embodiment.

FIG. 11B is a plan view illustrating a configuration of a semiconductor chip in FIG. 11A.

FIG. 12A is a cross-sectional view illustrating a configuration of a semiconductor light emitting device according to a first embodiment 0.

FIG. 12B is a plan view illustrating a configuration of a semiconductor chip in FIG. 12A.

FIG. 13A is a cross-sectional view illustrating a configuration of a semiconductor light emitting device according to a first embodiment 1.

FIG. 13B is a plan view illustrating a configuration of a semiconductor chip in FIG. 13A.

FIG. 14A is a cross-sectional view illustrating a configuration of a semiconductor light emitting device according to a first embodiment 2.

FIG. 14B is a plan view illustrating a configuration of a semiconductor chip in FIG. 14A.

FIG. 15A is a cross-sectional view illustrating a configuration of a semiconductor light emitting device according to a first embodiment 3.

FIG. 15B is a plan view illustrating a configuration of a semiconductor chip in FIG. 15A.

FIG. 16A is a cross-sectional view illustrating a configuration of a semiconductor light emitting device according to a first embodiment 4.

FIG. 16B is a plan view illustrating a configuration of a semiconductor light emitting device in FIG. 16A.

FIG. 17A is a cross-sectional view illustrating a configuration of a semiconductor light emitting device according to a first embodiment 5.

FIG. 17B is a plan view illustrating a configuration of a semiconductor chip in FIG. 17A.

FIG. 18A is a cross-sectional view illustrating a configuration of a semiconductor light emitting device according to a first embodiment 6.

FIG. 18B is a plan view illustrating a configuration of a semiconductor chip in FIG. 18A.

FIG. 19A is a cross-sectional view illustrating a configuration of a semiconductor light emitting device according to a first embodiment 7.

FIG. 19B is a plan view illustrating a configuration of a semiconductor chip in FIG. 19A.

FIG. 20A is a cross-sectional view illustrating a configuration of a semiconductor light emitting device according to a first embodiment 8.

FIG. 20B is a cross-sectional view for describing a function of a semiconductor light emitting device in FIG. 20A.

FIG. 20C is a plan view illustrating a configuration of a semiconductor light emitting device in FIG. 20A.

FIG. 21 is a cross-sectional view illustrating a configuration of a semiconductor light emitting device according to a first embodiment 9.

FIG. 22A is a cross-sectional view illustrating a configuration of a semiconductor light emitting device according to a second embodiment 0.

FIG. 22B is a plan view illustrating a configuration of a semiconductor light emitting device in FIG. 22A.

FIG. 23 is a cross-sectional view illustrating a configuration of a semiconductor light emitting device according to a second embodiment 1.

FIG. 24 is a cross-sectional view illustrating a configuration of a semiconductor light emitting device according to a second embodiment 2.

FIG. 25 is a block diagram illustrating an example of an overall configuration of a vehicle control system.

FIG. 26 is an explanatory diagram illustrating an example of positions at which a vehicle exterior information detector and an imaging unit are installed.

### DESCRIPTION OF EMBODIMENTS

Hereinafter, embodiments of a semiconductor light emitting device will be described with reference to the drawings. Hereinafter, main components of the semiconductor light emitting device will be mainly described, but the semiconductor light emitting device may have components or functions that are not illustrated or described. The following description does not exclude components or functions that are not illustrated or described. Further, in the following description, description of components whose structures or functions are common between the plurality of embodiments may be omitted in subsequent embodiments.

### First Embodiment

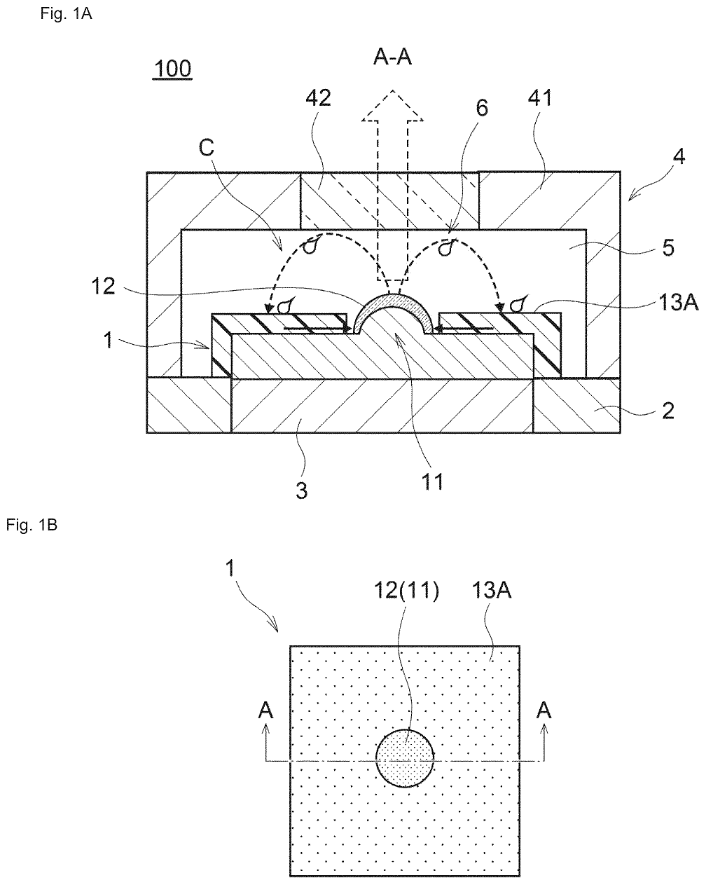

FIG. 1A is a cross-sectional view illustrating a configuration of one embodiment of a semiconductor light emitting device to which the present technology is applied. FIG. 1B is a plan view illustrating a configuration of a semiconductor chip in FIG. 1A. FIG. 1A illustrates a cross-section along a line A-A in FIG. 1B. A semiconductor light emitting device 100 includes a semiconductor chip 1 that is a light emitting element, a support substrate 2 that supports the semiconductor chip 1, a heat sink 3 that dissipates heat of the semiconductor chip 1 to an outside, and a sealing member 4 that seals the semiconductor chip 1. According to the semiconductor chip 1, a cooling fluid 6 sealed in a space 5 surrounded by the semiconductor chip 1, the support substrate 2, and the sealing member 4 is used to cause heat generated by a light emitting unit 11 of the semiconductor chip 1 to convect. Thus, the semiconductor light emitting device 100 according to the present embodiment includes a heat control member C that disperses, inside of the sealing member 4, heat of the light emitting unit 11 using the cooling fluid 6. Thus, the light emitting unit 11 is cooled by the cooling fluid 6.

The semiconductor chip 1 emits laser light from a front surface 12 of the light emitting unit 11 located at the center of one major surface of the semiconductor chip 1. The front surface 12 of the light emitting unit 11 has a protrusion part that is an emission surface of the laser light. The semiconductor chip 1 includes a first region 13A that is disposed around the light emitting unit 11 and has higher wettability than that of the front surface 12 of the light emitting unit 11. In other words, the first region 13A has hydrophilicity. The hydrophilicity (lipophilicity) is given to the first region 13A by giving functional groups (OH groups) such as carbonyl groups or carboxyl groups. Multiple functional groups (OH groups) adhere to the first region 13A according to the present embodiment compared to the front surface 12 of the light emitting unit 11. The functional groups to be adhered to the first region 13A are produced by performing ashing processing on an organic substance such as polyimide or resist, metals such as copper, nickel, and aluminum, or an inorganic substance such as glass or silicon. Note that, as a method for increasing wettability, a method other than a method for adhering functional groups may be used.

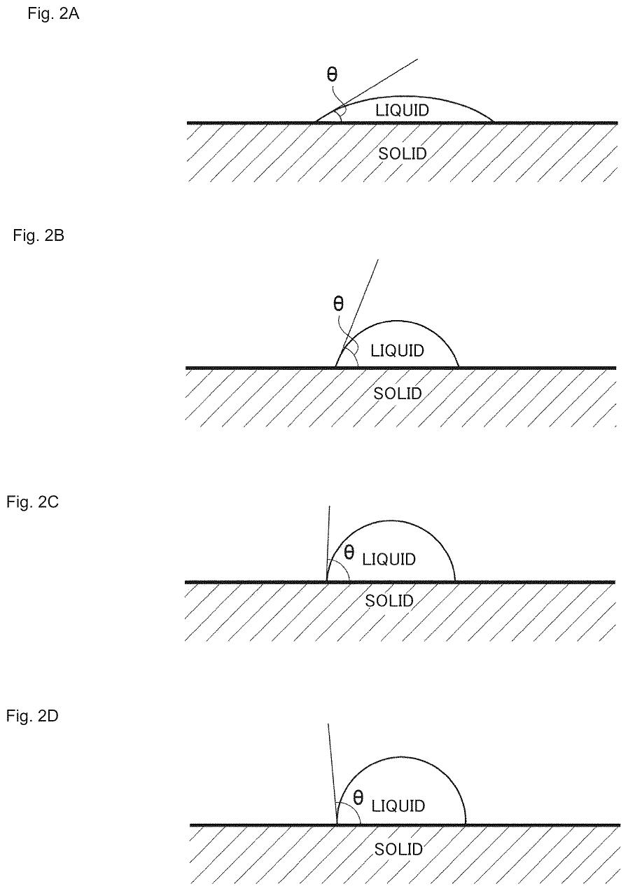

FIGS. 2A to 2D are explanatory diagrams of a relationship between wettability and a contact angle. Here, whether or not relative wettability is good is determined using a contact angle θ that is an angle (an angle inside of a liquid) formed between a liquid surface or a solid surface at a place at which a free surface of a stationary liquid is in contact with a solid wall. As the contact angle θ is smaller, the relative wettability is higher. For example, a liquid in FIG. 2A has the smaller contact angle θ than that of a liquid in FIG. 2B, and has high wettability with respect to the solid surface. For example, a liquid in FIG. 2C has the smaller contact angle θ than that of a liquid in FIG. 2D, and has high wettability with respect to the solid surface. The heat control member C according to the present embodiment includes the first region 13A that has the higher wettability than that of the front surface 12 of the light emitting unit 11, so that it is possible to cause the cooling fluid 6 to convect, and disperse the heat as illustrated in FIG. 1.

### Configuration of Semiconductor Chip

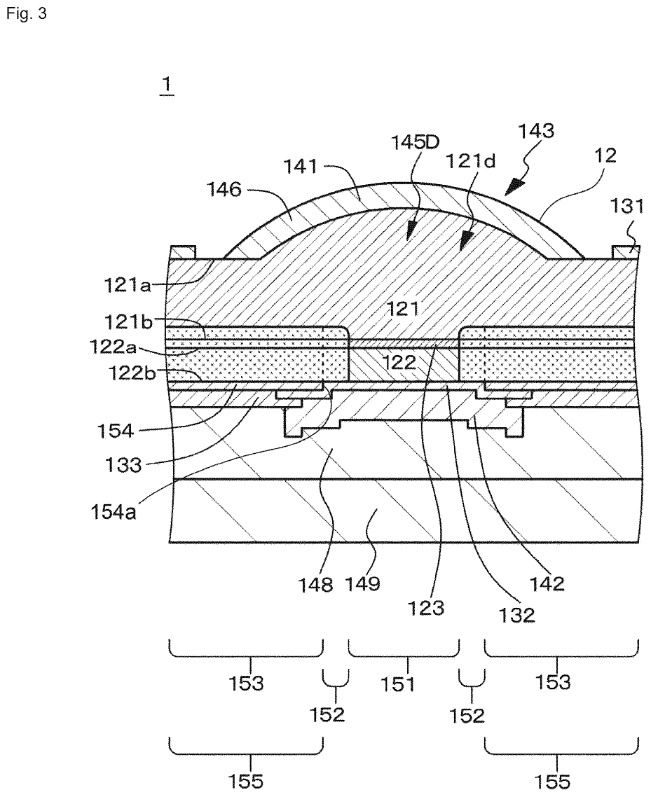

Hereinafter, the configuration of the semiconductor chip 1 will be described. FIG. 3 is a cross-sectional view illustrating a configuration of a configuration of the semiconductor chip. The semiconductor chip 1 includes a surface emitting laser (Vertical Cavity Surface Emitting Laser (VCSEL)) that emits laser light through a second light reflection layer from a top surface of a second compound semiconductor layer.

As illustrated in FIG. 3, the semiconductor chip 1 according to the present embodiment or the semiconductor chip 1 according to embodiments to be described later has, for example, a GaN-based compound semiconductor formed by laminating a first compound semiconductor layer 121 having a first conductive type (more specifically, n-type), an active layer (light emitting layer) 123, and a second compound semiconductor layer 122 having a second conductive type (more specifically, p-type). Note that the semiconductor chip 1 may be formed to include a compound semiconductor such as GaAs or InP. At least the first compound semiconductor layer 121, the active layer 123, and the second compound semiconductor layer 122 in FIG. 3 correspond to the light emitting unit 11 in FIG. 1.

The first compound semiconductor layer 121 includes a first surface 121a, and a second surface 121b that faces the first surface 121a. The active layer (light emitting layer) 123 faces the second surface 121b of the first compound semiconductor layer 121. The second compound semiconductor layer 122 includes a first surface 122a that faces the active layer 123, and a second surface 122b that faces the first surface 122a.

The first compound semiconductor layer 121 is formed of an n-GaN layer. The active layer 123 is a five-fold multiple quantum well structure formed by laminating an In0.04Ga0.96N layer (barrier layer) and an In0.16Ga0.84N layer (well layer). The second compound semiconductor layer 122 is formed of a p-GaN layer. A first electrode 131 is formed on the first surface 121a of the first compound semiconductor layer 121. On the other hand, a second electrode 132 is formed on the second compound semiconductor layer 122. The first electrode 131 is made of Ti/Pt/Au. The second electrode 132 is made of a transparent conductive material, more specifically, ITO. On an edge part of the first electrode 131, a pad electrode (not illustrated) is formed or connected that electrically connects with an external electrode or circuit and is made of, for example, Ti/Pt/Au or V/Pt/Au. On an edge part of the second electrode 132, a pad electrode 133 is formed or connected that electrically connects with an external electrode or circuit and is made of, for example, Pd/Ti/Pt/Au, Ti/Pd/Au, or Ti/Ni/Au.

### Paragraphs [0061] and [0067] of WO2018/083877

The semiconductor chip 1 includes a first light reflection layer 141 and a second light reflection layer 142 that are formed to sandwich a laminated structure made of the above-described GaN-based compound semiconductor. The first light reflection layer 141 is formed on a first surface 121a side of the first compound semiconductor layer 121. The second light reflection layer 142 is disposed on a second surface 122b side of the second compound semiconductor layer 122, and is formed on the second electrode 132. Further, the first light reflection layer 141 includes a concave mirror part 143, and the second light reflection layer 142 has a flat shape. The first light reflection layer 141 and the second light reflection layer 142 have a laminated structure (a total number of laminated layers of dielectric films: 20 layers) of Ta2O5 layers and SiO2 layers. The first light reflection layer 141 and the second light reflection layer 142 have such multilayer structures, yet are illustrated as one layer for simplicity of the drawings. Planar shapes of opening parts 154a provided to the first electrode 131, the first light reflection layer 141, the second light reflection layer 142, and an insulation layer (current constriction layer) 154 are circular.

The concave mirror part 143 of the first light reflection layer 141 includes a base part 145D that is formed of a protrusion part 121d of the first surface 121a of the first compound semiconductor layer 121, and a multilayer light reflection film 146 that is formed on part of a front surface (more specifically, a front surface of the base part 145D) of at least the base part 145D.

In the semiconductor chip 1, a current injection region 151, a current non-injection/inner region 152 that surrounds the current injection region 151, and a current non-injection/outer region 153 that surrounds the current non-injection/inner region 152 are formed. An orthographic projection image of a mode loss action region 155 and an orthographic projection image of the current non-injection/outer region 153 overlap. The current non-injection/inner region 152 and the current non-injection/outer region 153 are formed by plasma irradiation on a second surface of the second compound semiconductor layer 122, ashing processing on the second surface of the second compound semiconductor layer 122, and Reactive Ion Etching (RIE) processing on the second surface of the second compound semiconductor layer 122. Further, the current non-injection/inner region 152 and the current non-injection/outer region 153 are exposed to plasma particles (more specifically, argon, oxygen, nitrogen, and the like), and therefore conductivity of the second compound semiconductor layer 122 deteriorates and the current non-injection/inner region 152 and the current non-injection/outer region 153 are in a high resistance state. That is, the current non-injection/inner region 152 and the current non-injection/outer region 153 are formed by being exposed to the plasma particles on the second surface 122b of the second compound semiconductor layer 122.

In the semiconductor chip 1 according to the present embodiment, the second light reflection layer 142 is fixed to a support substrate 149 formed as a silicon semiconductor substrate by a solder joint method with a bonding layer 148 formed of a gold (Au) layer or a solder layer containing tin (Sn) interposed therebetween. The semiconductor chip 1 according to the present embodiment has the above-described predetermined arrangement relationship between the current injection region, the current non-injection region, and the mode loss action region, so that it is possible to control a relationship between magnitudes of oscillation mode loss given by the mode loss action region to a basic mode and a higher-order mode, and it is possible to further stabilize the basic mode by relatively increasing the oscillation mode loss to be given to the higher-order mode compared to the oscillation mode loss to be given to the basic mode.

As described above, the semiconductor chip 1 includes the concave mirror part 143 disposed on the front surface 12 of the light emitting unit 11, and becomes the surface emitting laser that reflects light from the active layer 123 at the concave mirror part 143 of the first light reflection layer 141. More specifically, the semiconductor chip 1 becomes the vertical cavity surface emitting laser. Note that the semiconductor chip 1 may be a surface emitting laser that includes a reflection layer that is not the concave mirror.

### Components Around Semiconductor Chip 1 and Effect Thereof

As illustrated in FIG. 1A, the support substrate 2 includes the heat sink 3, and supports the semiconductor chip 1. The semiconductor chip 1 is jointed to the heat sink 3. The heat sink 3 dissipates heat produced by the light emitting unit 11 of the semiconductor chip 1. The sealing member 4 includes a cap 41 and a transmission part 42 that surround and seal the semiconductor chip 1 on the support substrate 2, and has a planar view circular or rectangular bottomed cylindrical shape. The cap 41 is a lid that is made of, for example, a metal (made of, for example, aluminum). The cap 41 is airtightly fixed to the support substrate 2 so as to surround the semiconductor chip 1. The cap 41 is provided with a through-hole for providing the transmission part 42 at a position that is overlaid on the light emitting unit 11 of the semiconductor chip 1. The transmission part 42 is made of, for example, glass, and allows light emitted from the light emitting unit 11 of the semiconductor chip 1 to transmit therethrough. According to such a configuration, the semiconductor chip 1 is sealed by the support substrate 2, the heat sink 3, and the sealing member 4 in the semiconductor light emitting device 100.

The cooling fluid 6 is sealed in the space 5 between the sealing member 4 and the support substrate 2. More specifically, the cooling fluid 6 having the sufficiently smaller volume than the volume of air of the sealed space 5 is sealed inside of the sealing member 4. The cooling fluid 6 is a gas, a liquid, or a solid that takes in the heat, and evaporates, melts, or sublimes. For the cooling fluid 6, a material that can evaporate or sublime by heat generation of the semiconductor chip 1, and has the insulation property is used. For example, a liquid such as water or alcohol or a solid such as dry ice is used as the cooling fluid 6. The semiconductor chip 1 is cooled when the state of the cooling fluid 6 changes.

According to such a configuration, when the semiconductor light emitting device 100 emits light, and the semiconductor chip 1 generates heat in the light emitting unit 11, the cooling fluid 6 heated by the front surface 12 of the light emitting unit 11 evaporates, becomes a gas, and cools the light emitting unit 11. Subsequently, the cooling fluid 6 that has become the gas disperses and convects inside of the sealing member 4 (space 5). As described above, the heat control member C according to the present embodiment includes the first region 13A that has the wettability higher than that of the front surface 12 of the light emitting unit 11. Further, the first region 13A is disposed around the light emitting unit 11. Hence, the cooling fluid 6 that has become the gas and flown from the inside to the outside in the space 5 condenses and adheres in the first region 13A that has the high wettability. Further, the cooling fluid 6 accumulated in the first region 13A gathers on a light emitting unit 11 side, and evaporates again on the front surface 12 of the light emitting unit 11. Thus, the heat control member C according to the present embodiment causes the heat of the light emitting unit 11 using the cooling fluid 6 to convect between the light emitting unit 11 and the sealing member 4. Consequently, the heat control member C can circulate the cooling fluid 6 in the semiconductor light emitting device 100, and disperse inside of the sealing member 4 the heat of the light emitting unit 11 using the cooling fluid 6. The semiconductor light emitting device 100 according to the present embodiment can efficiently cool the light emitting unit 11, and obtain original light emission characteristics as designed (the same applies to the following embodiments).

Further, according to the configuration of the present embodiment, it is also possible to improve output, reliability, or temperature characteristics by efficiently cooling the light emitting unit 11. Further, the light emitting unit 11 is cooled by circulating the cooling fluid 6 in the semiconductor light emitting device 100, and consequently can be cooled in a self-consistent manner. Consequently, it is possible to reduce a failure rate by making movable parts unnecessary, and reduce electrical loss, too. Further, the cooling fluid 6 circulates, so that it is possible to move charges produced on the surface in the sealing member 4, and prevent damages on the semiconductor chip 1 due to electrostatic discharge caused by accumulation of the charges.

Furthermore, as illustrated in FIG. 3, the concave mirror part 143 that is the concave mirror of the first light reflection layer 141 among the first light reflection layer 141 and the second light reflection layer 142 constituting the Distributed Bragg Reflector (DBR) protrudes outward, so that it is possible to increase the area of the front surface 12 of the light emitting unit 11 compared to a case where the concave mirror part 143 is flat. Consequently, it is possible to efficiently cool the front surface 12 of the light emitting unit 11. Further, the front surface of the concave mirror part 143 (the front surface 12 of the light emitting unit 11) becomes a rough surface, so that it is easy to collect the cooling fluid 6 from the surroundings, and it is also possible to improve cooling efficiency.

### Second Embodiment

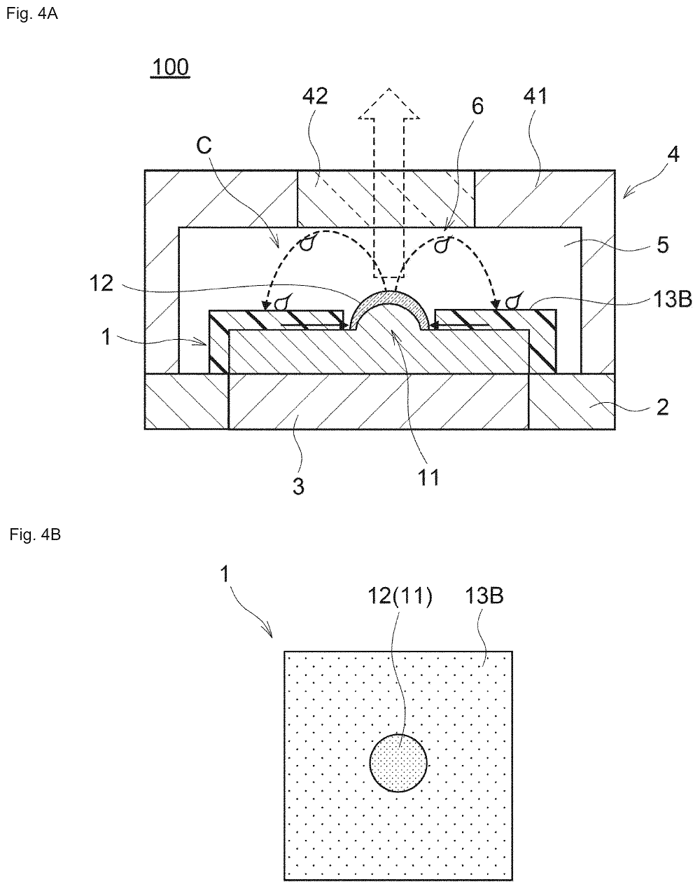

FIG. 4A is a cross-sectional view illustrating a configuration of a semiconductor light emitting device according to the second embodiment. FIG. 4B is a plan view illustrating a configuration of a semiconductor chip in FIG. 4A. The heat control member C according to the present embodiment includes a first region 13B in place of the first region 13A according to the first embodiment. The first region 13B is disposed around the light emitting unit 11, and has a surface tension different from that of the front surface 12 of the light emitting unit 11. This first region 13B is formed such that a surface tension _{Y}c is larger than that of the front surface 12 of the light emitting unit 11. This makes it possible to increase wettability of the first region 13B. In this case, by making the surface tension of the first region 13B close to a critical surface tension _{Y}c, it is possible to make the cooling fluid 6 more wet in the first region 13B. According to the configuration according to the present embodiment, it is possible to make the cooling fluid 6 more easily adhere to the first region 13B, encourage convection of the cooling fluid 6 inside of the sealing member 4, and efficiently cool the light emitting unit 11.

### Third Embodiment

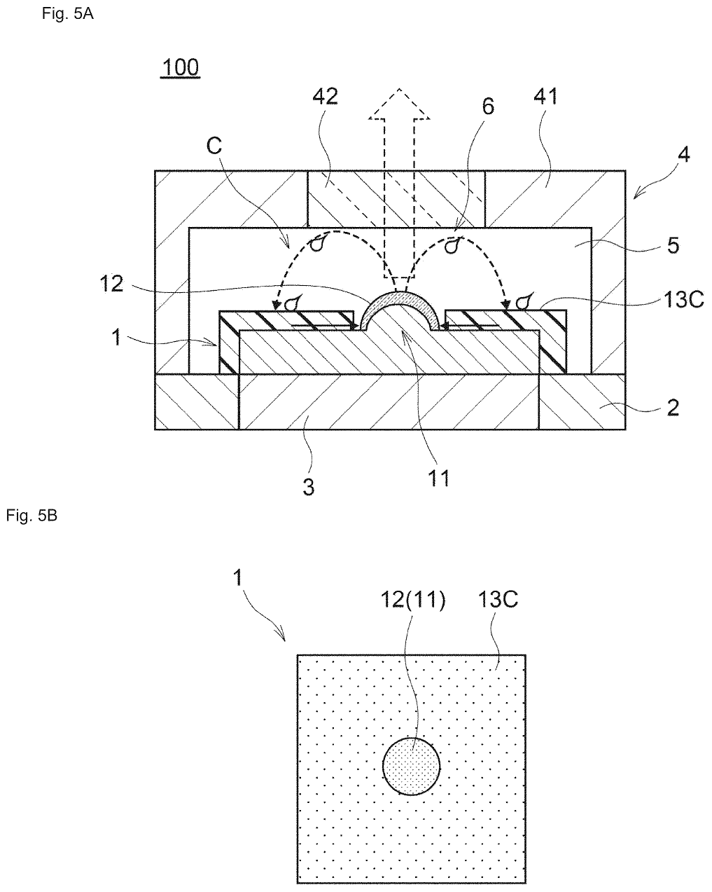

FIG. 5A is a cross-sectional view illustrating a configuration of a semiconductor light emitting device according to the third embodiment. FIG. 5B is a plan view illustrating a configuration of a semiconductor chip in FIG. 5A. The heat control member C according to the present embodiment includes a first region 13C in place of the first region 13A according to the first embodiment. The first region 13C is disposed around the light emitting unit 11, and has surface roughness different from that of the front surface 12 of the light emitting unit 11. Consequently, it is possible to vary the surface roughness of the light emitting unit 11 and the first region 13C. For example, the surface roughness of the front surface 12 of the light emitting unit 11 may be made rougher than the surface roughness of the first region 13C, and the surface roughness of the first region 13C may be made rougher than the surface roughness of the front surface 12 of the light emitting unit 11. In this case, the difference in surface roughness is desirably 1% or more, and is more desirably 10% or more. Here, in a case of a front surface having hydrophilicity or lipophilicity, as the surface roughness becomes greater, the hydrophilicity or the lipophilicity becomes higher, and, in a case of a front surface having water repellency or oil repellency, as the surface roughness becomes greater, the water repellency or the oil repellency becomes higher. Hence, in the present embodiment, when, for example, the first region 13C is the front surface having high hydrophilicity, the surface roughness of the front surface is increased.

In the present embodiment, by varying the surface roughness of the first region 13C and the front surface 12 of the light emitting unit 11, it is possible to make the cooling fluid 6 more wet in the first region 13C. Consequently, it is possible to make the cooling fluid 6 more easily adhere to the first region 13C, encourage convection of the cooling fluid 6 in the sealing member 4, and efficiently cool the light emitting unit 11.

### ARRAY TYPE

### Fourth Embodiment

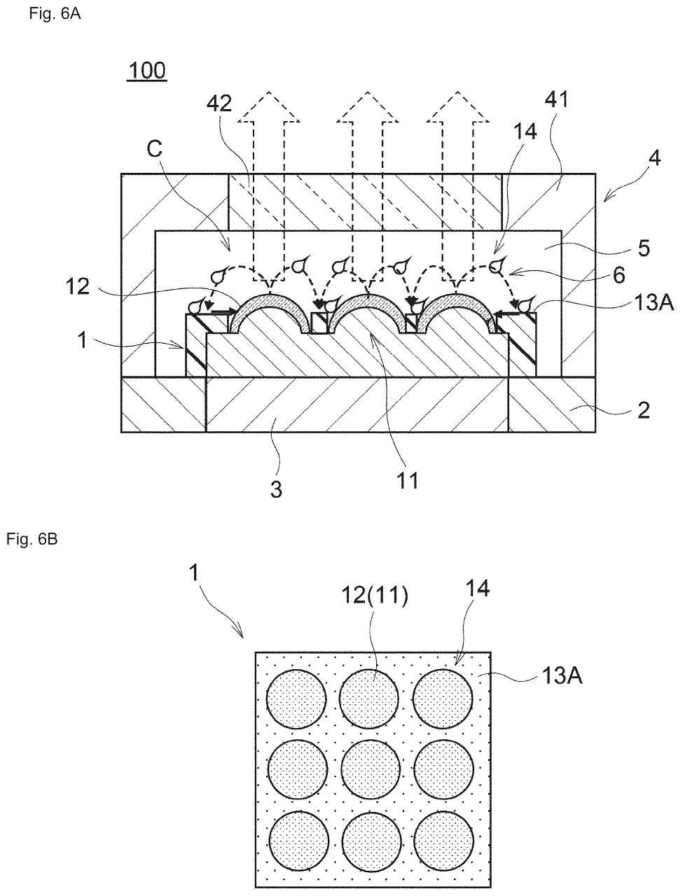

FIG. 6A is a cross-sectional view illustrating a configuration of a semiconductor light emitting device according to the fourth embodiment. FIG. 6B is a plan view illustrating a configuration of a semiconductor chip in FIG. 6A. The semiconductor chip 1 according to the present embodiment includes an array part 14 that includes a plurality of the light emitting units 11 disposed in a two-dimensional direction. As illustrated in FIG. 6B, the nine light emitting units 11 disposed in a plurality of rows and a plurality of columns, more specifically, three rows and three columns are disposed in the semiconductor chip 1. Note that the semiconductor chip 1 may include the array part 14 that includes the plurality of light emitting units 11 disposed in a one-dimensional direction. The sealing member 4 includes the transmission part 42 that is formed in size covering all of the light emitting units 11. Thus, the sealing member 4 seals the array part 14, and allows light emitted from each of the plurality of light emitting units 11 to transmit through the transmission part 42.

The first region 13A in the semiconductor chip 1 according to the present embodiment is disposed so as to surround the protruding front surfaces 12 on the surface including the front surfaces 12 of the nine light emitting units 11. In other words, the first region 13A is disposed at a portion except the front surfaces 12 of the nine light emitting units 11. The first region 13A may have the higher wettability than that of the front surface 12 of the light emitting unit 11 similarly to the first embodiment. Furthermore, the first region 13A may have the surface tension _{Y}c larger than that of the front surface 12 of the light emitting unit 11 similarly to the second embodiment, or may have surface roughness different from that of the front surface 12 of the light emitting unit 11 similarly to the third embodiment.

The heat control member C according to the present embodiment can also make the cooling fluid 6 more easily adhere to the first region 13C, encourage convection of the cooling fluid 6 in the sealing member 4, and efficiently cool the light emitting units 11. Further, by causing the cooling fluid 6 that has become the gas to convect in the first region 13A disposed so as to surround the plurality of light emitting units 11, it is possible to cool all of the light emitting units 11 provided in the array part 14. Consequently, it is possible to suppress temperature variations between the plurality of light emitting units 11 provided in the array part 14, and make the light emission characteristics planarly uniform.

### Fifth Embodiment

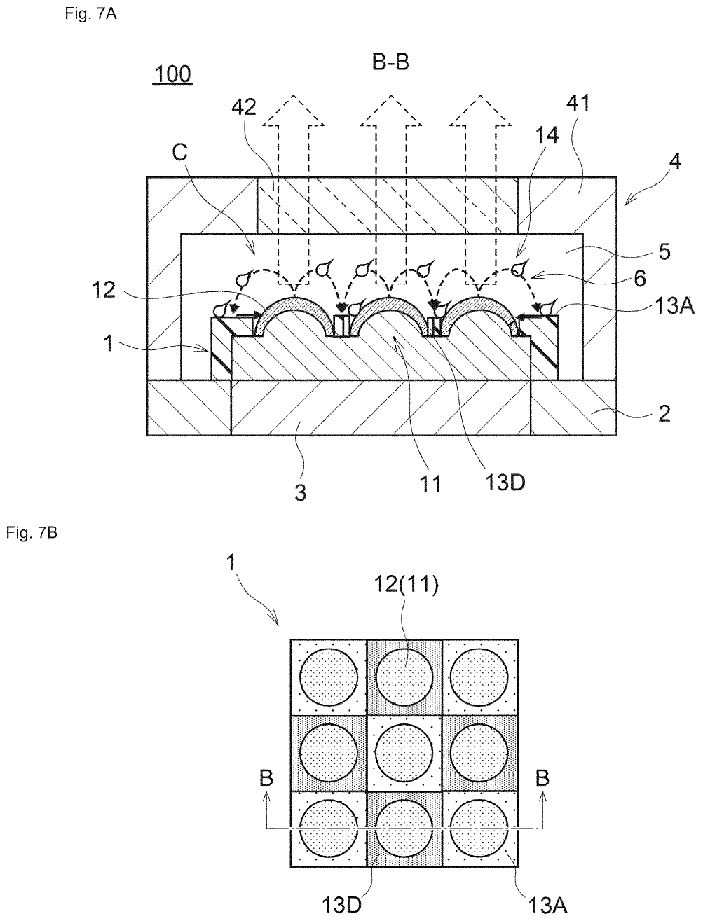

FIG. 7A is a cross-sectional view illustrating a configuration of a semiconductor light emitting device according to the fifth embodiment. FIG. 7B is a plan view illustrating a configuration of a semiconductor chip in FIG. 7A. FIG. 7A illustrates a cross-section along a line B-B in FIG. 7B. That the semiconductor chip 1 according to the present embodiment is the same as that of the fourth embodiment in including the array part 14 including the plurality of light emitting units 11, and provides a similar effect. However, the semiconductor chip 1 according to the present embodiment differs from the semiconductor chip 1 according to the fourth embodiment in varying the wettability per semiconductor chip 1 light emitting unit 11 according to the present embodiment.

For example, the first region 13A around the light emitting unit 11 on the outer side in FIG. 7A is formed to have higher hydrophilicity than that of the front surface 12 of the light emitting unit 11. By contrast with this, a first region 13D around the light emitting unit 11 at the center in FIG. 7A is formed to have lower hydrophilicity than that of the first region 13A. Thus, by varying the degree of cooling per light emitting unit 11 in the array part 14, it is possible to individually control the light emission characteristics of the light emitting units 11. Further, by varying wettability around each light emitting unit 11, heat characteristics or the like of the plurality of light emitting units 11 having different light emission characteristics may be made uniform. Further, the wettability may be varied at two or more multiple stages.

### Sixth Embodiment

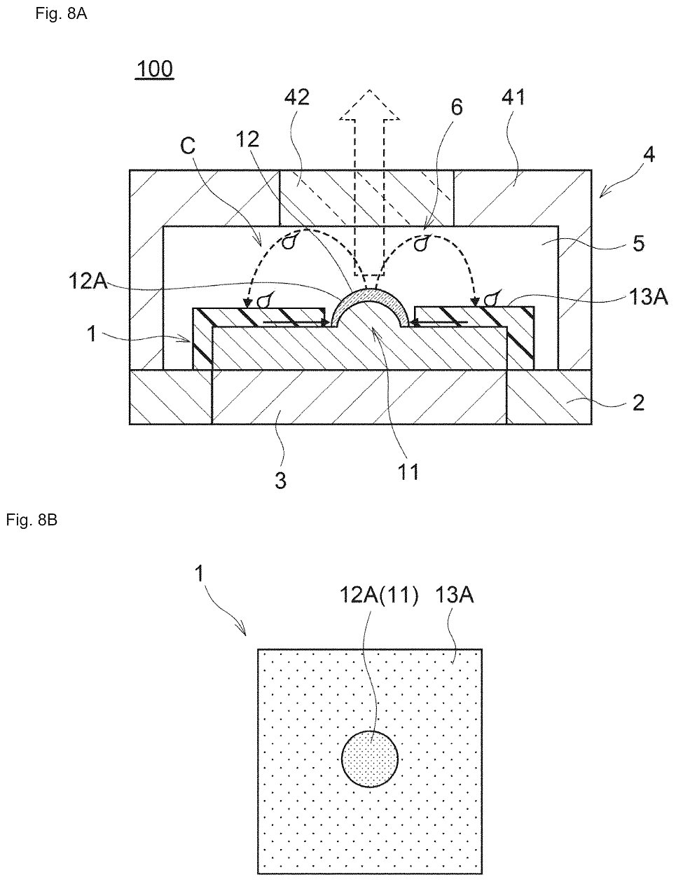

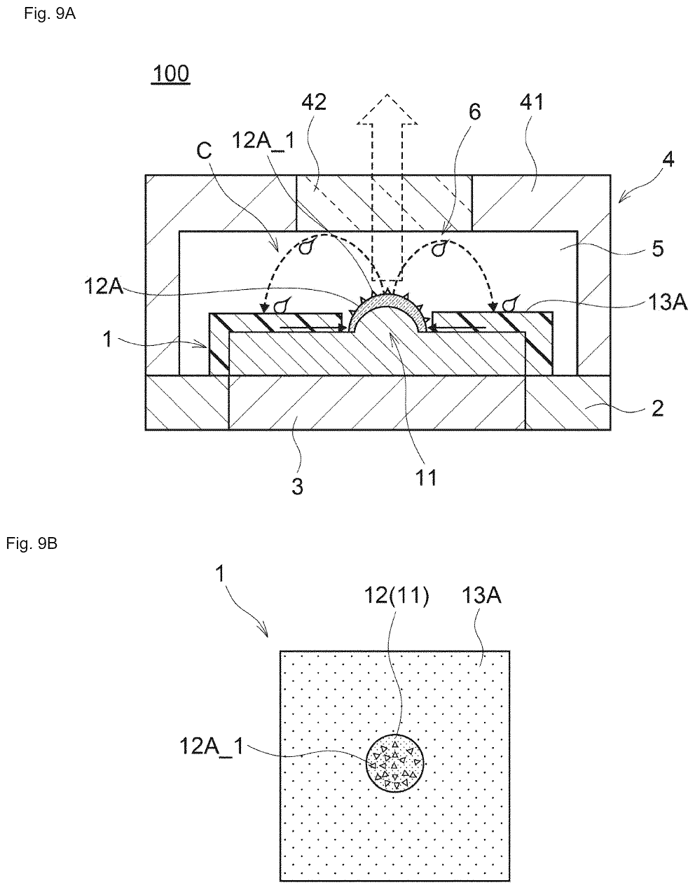

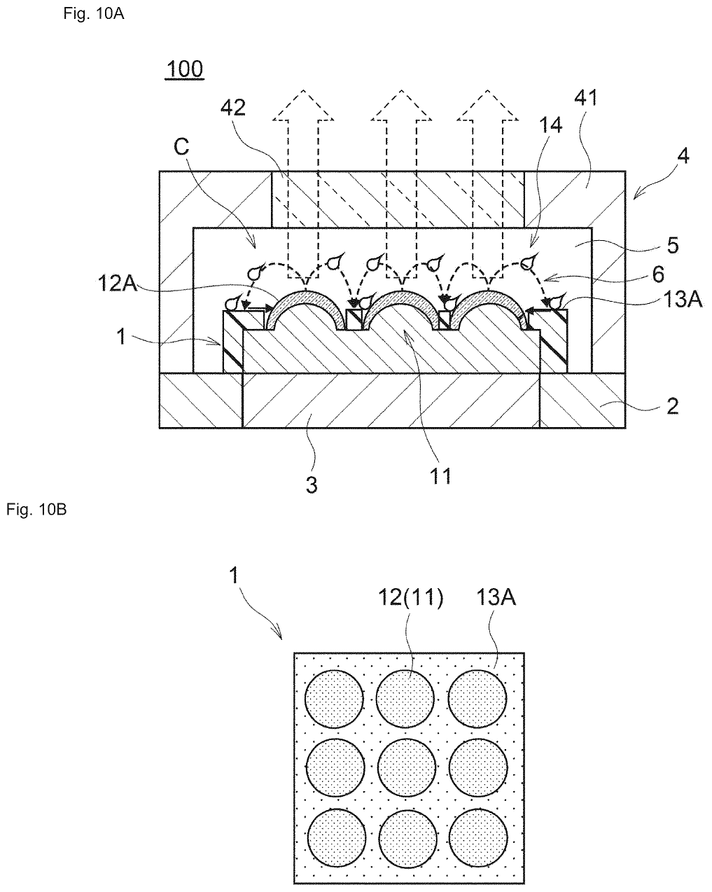

FIG. 8A is a cross-sectional view illustrating a configuration of a semiconductor light emitting device according to the sixth embodiment. FIG. 8B is a plan view illustrating a configuration of a semiconductor chip in FIG. 8A. The heat control member C according to the present embodiment includes a second region 12A that is disposed on the front surface 12 of the light emitting unit 11, and has higher water repellency or oil repellency than that of the first region 13A. The second region 12A is formed such that water repellency or oil repellency becomes higher by adhering more chemical substances such as saturated fluoroalkyl groups, alkylsilyl groups, fluorosilyl groups, or long chain alkyl groups to the front surface 12 of the light emitting unit 11 than to the first region 13A. Note that it is particularly desirable to adhere trifluoromethyl groups (CF3—) among the saturated fluoroalkyl groups to the second region 12A to enhance water repellency or oil repellency.

As described above, by making the water repellency or the oil repellency of the second region 12A higher than that of the first region 13A, it is possible to make hydrophilicity or lipophilicity of the first region 13A relatively higher than that of the second region 12A. Consequently, it is possible to make the cooling fluid 6 more easily adhere to the first region 13A, encourage convection of the cooling fluid 6 inside of the sealing member 4, and efficiently cool the light emitting unit 11. Consequently, it is possible to encourage circulation of the cooling fluid 6 and efficiently cool the light emitting unit 11.

### SEVENTH EMBODIMENT

### Seventh Embodiment

FIG. 9A is a cross-sectional view illustrating a configuration of a semiconductor light emitting device according to the seventh embodiment. FIG. 9B is a plan view illustrating a configuration of a semiconductor chip in FIG. 9A. The heat control member C according to the present embodiment includes a plurality of protrusion parts 12A_1 provided on the front surface 12 (second region 12A) of the light emitting unit 11. This protrusion part 12A_1 is formed small to such a degree that laser light emitted as parallel light from the front surface 12 of the light emitting unit 11 is not diffused. These protrusion parts 12A_1 can make the wettability of the first region 13A relatively high by making the wettability of the front surface 12 of the light emitting unit 11 low, encourage convection of the cooling fluid 6, and efficiently cool the light emitting unit 11.

### Eighth Embodiment

FIG. 10A is a cross-sectional view illustrating a configuration of a semiconductor light emitting device according to the eighth embodiment. FIG. 10B is a plan view illustrating a configuration of a semiconductor chip in FIG. 10A. That the semiconductor chip 1 according to the present embodiment is the same as the semiconductor chip 1 according to the fourth embodiment in including the array part 14 including the plurality of light emitting units 11, and provides a similar effect. However, the semiconductor chip 1 according to the present embodiment differs from the semiconductor chip 1 according to the fourth embodiment in that the wettability of the front surface 12 (second region 12A) of the light emitting unit 11 is lower than that of the first region 13A. To make the wettability low, more chemical substances such as the saturated fluoroalkyl groups may be adhered to the front surface 12 of the light emitting unit 11 than to the first region 13A similarly to the sixth embodiment, or the plurality of fine protrusion parts 12A_1 may be provided on the front surface 12 of the light emitting unit 11 similarly to the seventh embodiment. Consequently, even the configuration including the array part 14 can encourage convection of the cooling fluid 6 and efficiently cool the light emitting unit 11.

### Ninth Embodiment

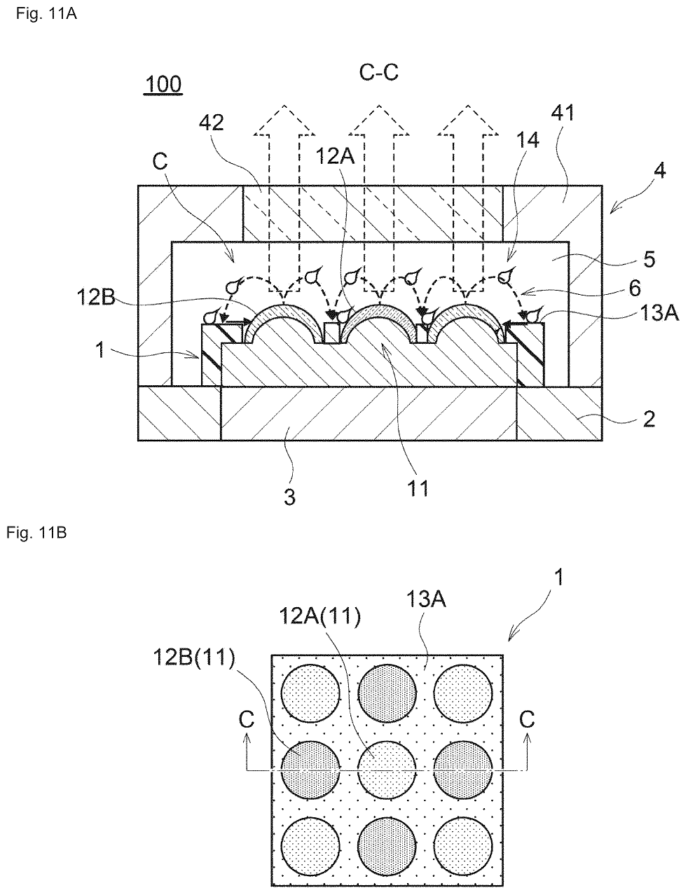

FIG. 11A is a cross-sectional view illustrating a configuration of a semiconductor light emitting device according to the ninth embodiment. FIG. 11B is a plan view illustrating a configuration of a semiconductor chip in FIG. 11A. That the semiconductor chip 1 according to the present embodiment is the same as the semiconductor chip 1 according to the eighth embodiment in including the array part 14 including the plurality of light emitting units 11, and provides a similar effect. However, the semiconductor chip 1 according to the present embodiment differs from the semiconductor chip 1 according to the eighth embodiment in varying the wettability of the front surface 12 for each of the plurality of light emitting units 11.

The front surface 12 (second region 12A) of the light emitting unit 11 illustrated on the inner side in FIG. 11A has lower wettability than that of the front surface 12 (second region 12B) of the light emitting unit 11 illustrated on the outer side in FIG. 11A. To make the wettability of the front surface 12 (second region 12A) low, more chemical substances such as the saturated fluoroalkyl groups may be adhered similarly to the sixth embodiment, or the plurality of fine protrusion parts 12A_1 may be provided similarly to the seventh embodiment. Consequently, even the configuration including the array part 14 can encourage convection of the cooling fluid 6 and efficiently cool the light emitting unit 11, and, in addition, it is possible to individually control the light emission characteristics (e.g., output or temperature characteristics) of the light emitting unit 11. Further, by varying the wettability of the front surface 12 of each light emitting unit 11, the heat characteristics of the plurality of light emitting units 11 having different light emission characteristics may be made uniform. Further, the wettability may be varied at two or more multiple stages.

### Tenth Embodiment

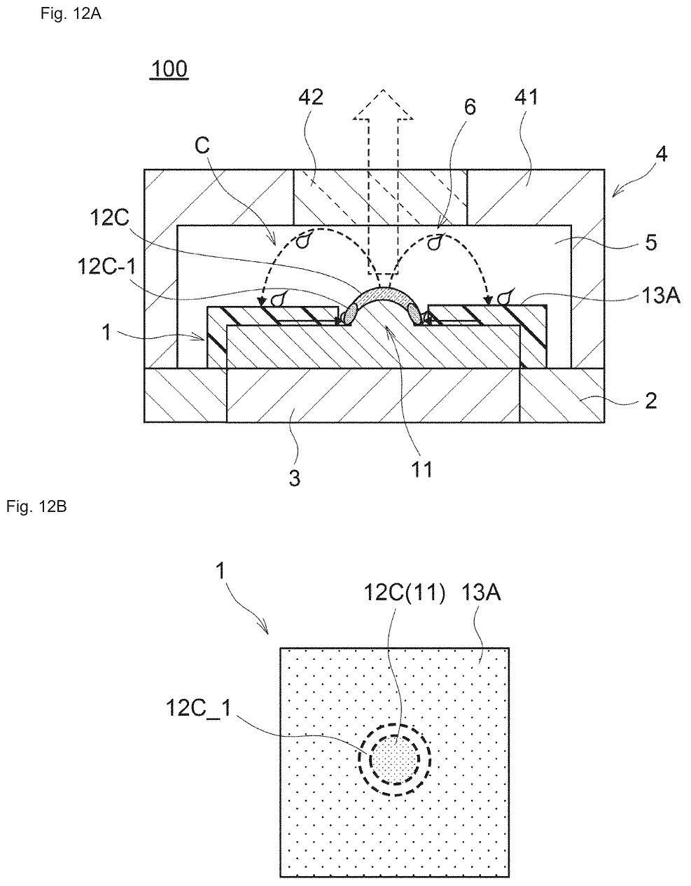

FIG. 12A is a cross-sectional view illustrating a configuration of a semiconductor light emitting device according to the tenth embodiment. FIG. 12B is a plan view illustrating a configuration of a semiconductor chip in FIG. 12A. FIG. 12A illustrates a cross-section along a line C-C in FIG. 12B. The light emitting unit 11 according to the present embodiment includes a protrusion part 12C having the upper surface on which a light emission surface is disposed. At least part of side surfaces of the protrusion part 12C, a roughened region 12C_1 is arranged. More specifically, as illustrated in FIG. 12A, the roughened region 12C_1 formed by roughening is formed at an outer circumferential portion (foot portion) of the protrusion part 12C on the front surface 12 of the light emitting unit 11. The roughened region 12C_1 is formed by performing dry etching or chemical treatment in a state where portions other than the outer circumferential portion of the protrusion part 12C that is a multilayer film of a dielectric (SiO2 or Ta2O5) is masked.

According to such a configuration, the heat control member C includes the roughened region 12C_1 disposed on at least part of the side surfaces of the protrusion part 12C, so that it is possible to increase the surface area of the roughened region 12C_1. Further, by disturbing the flow of the cooling fluid 6 circulating around the protrusion part 12C, it is possible to efficiently cool the light emitting unit 11. Note that a portion, that is, a center portion of the protrusion part 12C except the outer circumference roughened for the roughened region 12C_1 functions as the concave mirror part 143 illustrated in FIG. 3. In this case, the first region 13A may be made of the same material as that of the concave mirror part 143, yet may be an insulating film of SiO2 or SiN.

### Eleventh Embodiment

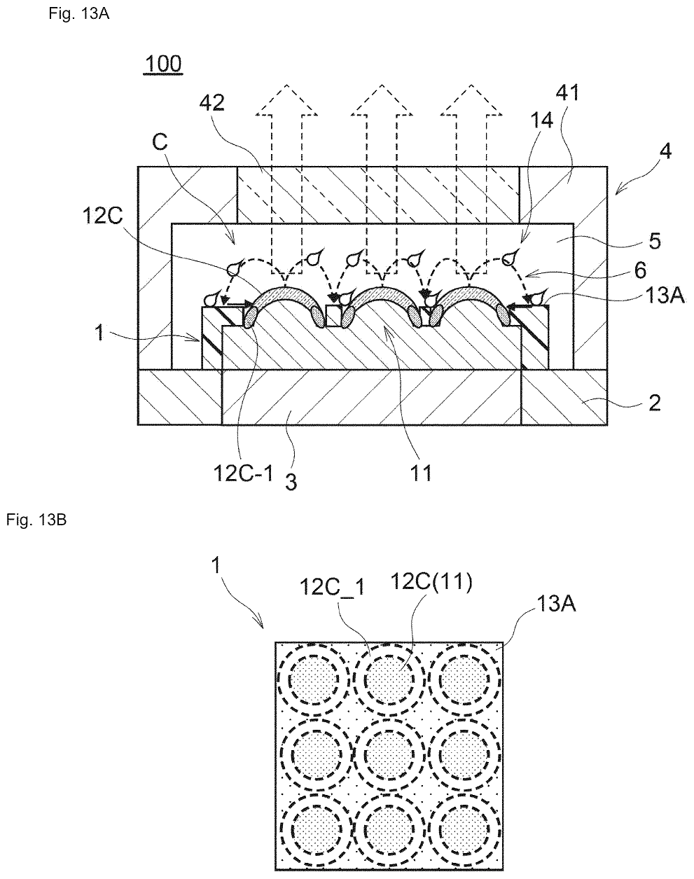

FIG. 13A is a cross-sectional view illustrating a configuration of a semiconductor light emitting device according to the eleventh embodiment. FIG. 13B is a plan view illustrating a configuration of a semiconductor chip in FIG. 13A. That the configuration according to the present embodiment is the same as the semiconductor chip 1 according to the first embodiment in including the array part 14 including the plurality of light emitting units 11, and provides a similar effect. Further, that the roughened region 12C_1 formed by roughening is provided at the outer circumferential portion of the protrusion part 12C on the front surface 12 of the light emitting unit 11 is the same as that of the semiconductor chip 1 according to the tenth embodiment, and provides a similar effect. Consequently, even the configuration including the array part 14 can encourage convection of the cooling fluid 6 and efficiently cool the light emitting unit 11.

### Twelfth Embodiment

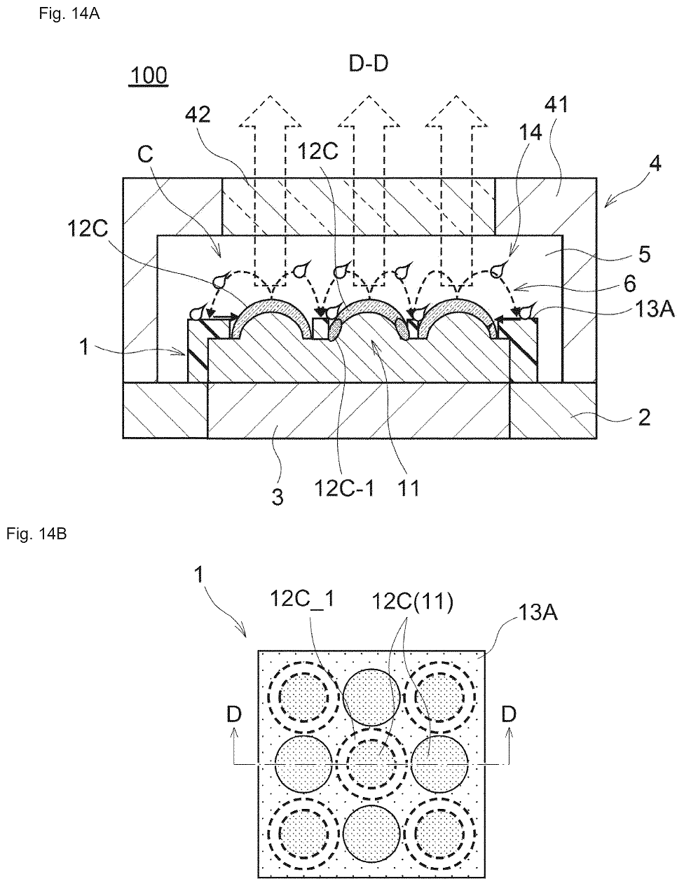

FIG. 14A is a cross-sectional view illustrating a configuration of a semiconductor light emitting device according to the twelfth embodiment. FIG. 14B is a plan view illustrating a configuration of a semiconductor chip in FIG. 14A. FIG. 14A illustrates a cross-section along a line D-D in FIG. 14B. That the configuration according to the present embodiment is the same as the semiconductor chip 1 according to the eleventh embodiment in including the array part 14 including the plurality of light emitting units 11, and provides a similar effect. Further, that the roughened region 12C_1 formed by roughening is provided at the outer circumferential portion of the protrusion part 12C on the front surface 12 of the light emitting unit 11 is the same as that of the semiconductor chip 1 according to the eleventh embodiment, and provides a similar effect. By contrast with this, the semiconductor chip 1 according to the present embodiment differs from the semiconductor chip 1 according to the eleventh embodiment in including both of the light emitting unit 11 including the roughened region 12C_1, and the light emitting unit 11 including no roughened region 12C_1. For example, the light emitting unit 11 on the outer side in FIG. 7A includes no roughened region 12C_1, and the light emitting unit at the center includes the roughened region 12C_1. Thus, according to the configuration according to the present embodiment, by varying the degree of cooling per light emitting unit 11, it is possible to individually control the light emission characteristics of the light emitting units 11. Further, similarly, the heat characteristics of the plurality of light emitting units 11 having different light emission characteristics may be made uniform.

### Thirteenth Embodiment

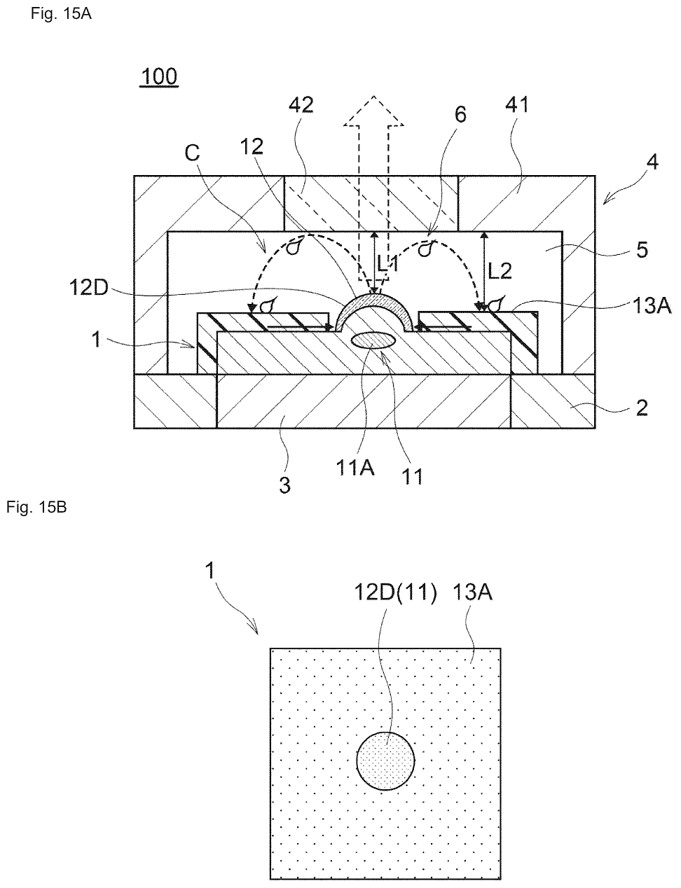

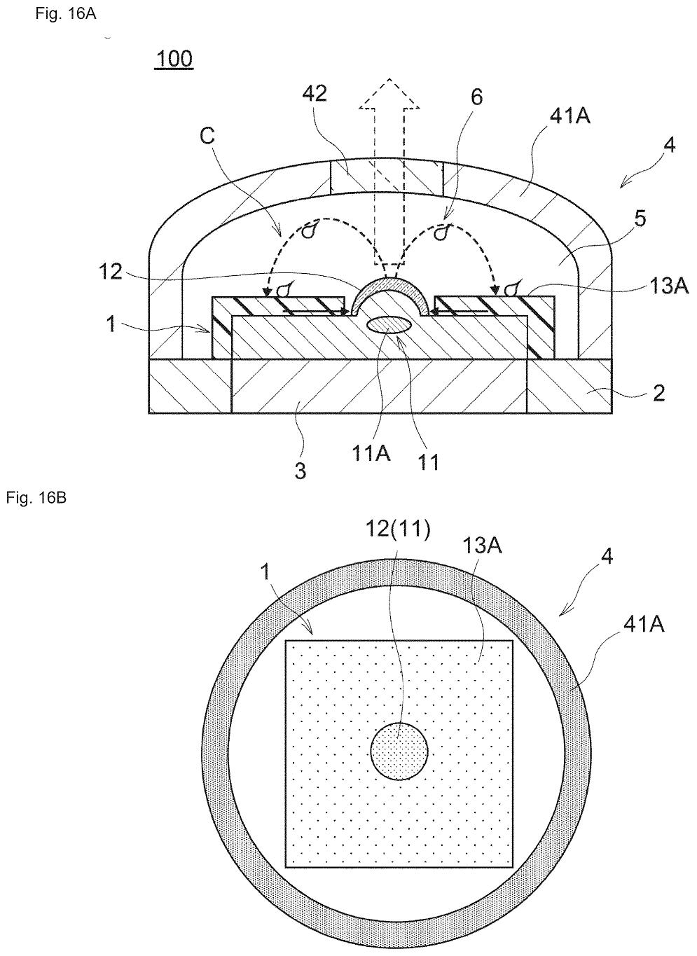

FIG. 15A is a cross-sectional view illustrating a configuration of a semiconductor light emitting device according to the thirteenth embodiment. FIG. 15B is a plan view illustrating a configuration of a semiconductor chip in FIG. 15A. The semiconductor light emitting device 100 according to the present embodiment employs an identical configuration to those of the semiconductor light emitting device 100 according to the first embodiment and the semiconductor light emitting devices 100 according to the other embodiments. The heat control member C according to the present embodiment includes a second region 12D that is disposed on the front surface of the light emitting unit 11, and has a higher temperature than that of the first region 13A at a time of light emission of the light emitting unit 11. In the light emitting unit 11, a high temperature part 11A that generates heat due to laser oscillation and has a high temperature heats the second region 12D of the front surface 12, too.

Further, the semiconductor chip 1 includes the concave mirror part 143 as illustrated in FIG. 2, so that the front surface 12 of the light emitting unit 11 protrudes outward, and is at a close distance to the transmission part 42 of the sealing member 4. More specifically, as illustrated in FIG. 15A, a distance L1 from a distal end of the front surface 12 that protrudes from the light emitting unit 11 to the inner surface of the transmission part 42 is shorter than a distance L2 from the first region 13A to the inner surface of the cap 41. That is, the second region 12D is disposed on a side closer to the positions of the inner surfaces of the transmission part 42 and the cap 41 than the first region 13A. Consequently, the space 5 above the light emitting unit 11 narrows, and there is little warming air, so that the space 5 above the light emitting unit 11 is heated.

On the other hand, the first region 13A has a lower temperature than that of the front surface 12 of the light emitting unit 11, so that a temperature gradient is produced in the sealing member 4, and it is possible to cause the cooling fluid 6 to convect without staying on the light emitting unit 11. Consequently, it is possible to efficiently circulate the cooling fluid 6. The heat control member C according to the present embodiment causes convection of heat inside of the sealing member 4 according to the temperature difference between the first region 13A and the second region 12D. Consequently, it is possible to cause the cooling fluid 6 to convect and efficiently cool the light emitting unit 11. Note that the other embodiments where the distance L1 and the distance L2 have a similar relationship for the heat control member C can also provide a similar effect.

Further, the configuration is employed where the cooling fluid 6 hardly stays on the front surface 12 (second region 12D) of the light emitting unit 11, so that it is possible to prevent the cooling fluid 6 from staying in a route of the laser light emitted from the light emitting unit 11, and suppress deterioration of optical characteristics of the semiconductor light emitting device 100. Further, the concave mirror part 143 can increase the surface area of the front surface 12 of the light emitting unit 11, so that it is possible to improve cooling efficiency. Further, the concave mirror part 143 provides a protrusion part whose curved surface is spherical to the front surface 12 of the light emitting unit 11, so that it is possible to make an emission angle of laser vertical at all times, and prevent the emission angle from fluctuating due to a difference between refractive indices of the concave mirror part 143 and the cooling fluid 6.

### Fourteenth Embodiment

FIG. 16A is a cross-sectional view illustrating a configuration of a semiconductor light emitting device according to the fourteenth embodiment. FIG. 16B is a plan view illustrating a configuration of a semiconductor light emitting device in FIG. 16A. As illustrated in FIG. 16A, the sealing member 4 according to the present embodiment includes a dome-shaped cap 41A. More specifically, the cap 41A is a lid whose center of an end surface protrudes in a curved shape, whose thickness is substantially the same, and whose cross section is formed in a curved shape. Hence, at least part of the inner surface of the sealing member 4 has a curved shape. Consequently, it is possible to cause the cooling fluid 6 to convect along the curved surface, and efficiently cool the light emitting unit 11.

### Fifteenth Embodiment

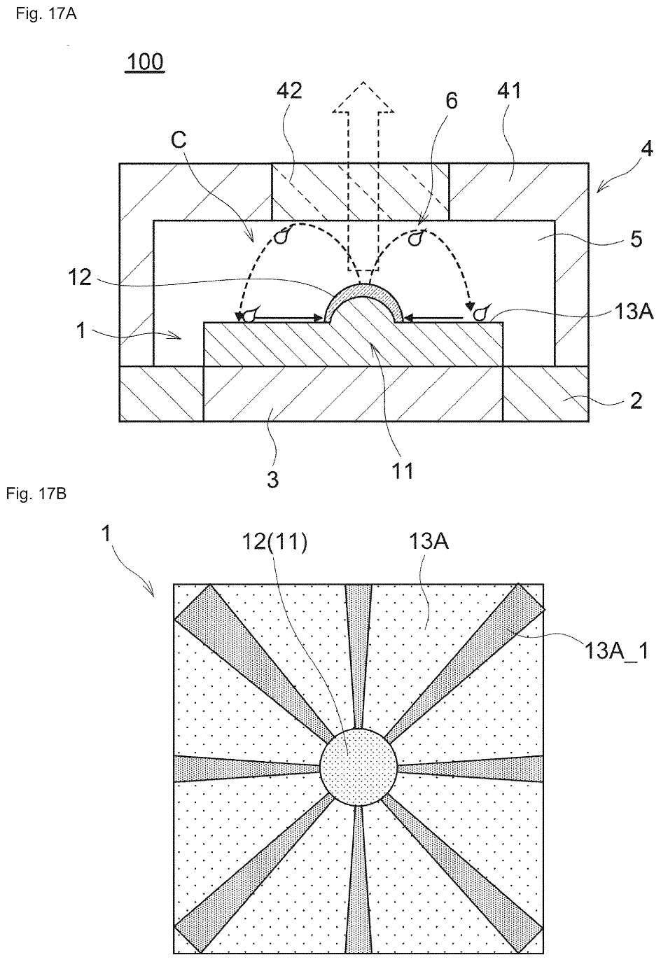

FIG. 17A is a cross-sectional view illustrating a configuration of a semiconductor light emitting device according to the fifteenth embodiment. FIG. 17B is a plan view illustrating a configuration of a semiconductor chip in FIG. 17A. The semiconductor light emitting device 100 according to the present embodiment includes the semiconductor chip 1 that includes the light emitting unit 11, and includes a plurality of grooves 13A_1 around the light emitting unit 11. The plurality of grooves 13A_1 is disposed on one major surface of the first region 13A of the semiconductor chip 1. Each of the plurality of grooves 13A_1 radially extends from the light emitting unit 11 at the center part to an end part of the one major surface. The widths of the plurality of grooves 13A_1 may be wider on a farther side than on a closer side to the light emitting unit 11. The heat control member C according to the present embodiment includes the plurality of grooves 13A_1. Consequently, it is possible to gather on the light emitting unit 11 side the cooling fluid 6 condensed on the one major surface of the first region 13A using a capillary action in the plurality of grooves 13A_1. Consequently, it is possible to circulate the cooling fluid 6 and efficiently cool the light emitting unit 11. Note that the plurality of grooves 13A_1 may be provided extending spirally instead of radially on the one major surface of the first region 13A.

### Sixteenth Embodiment

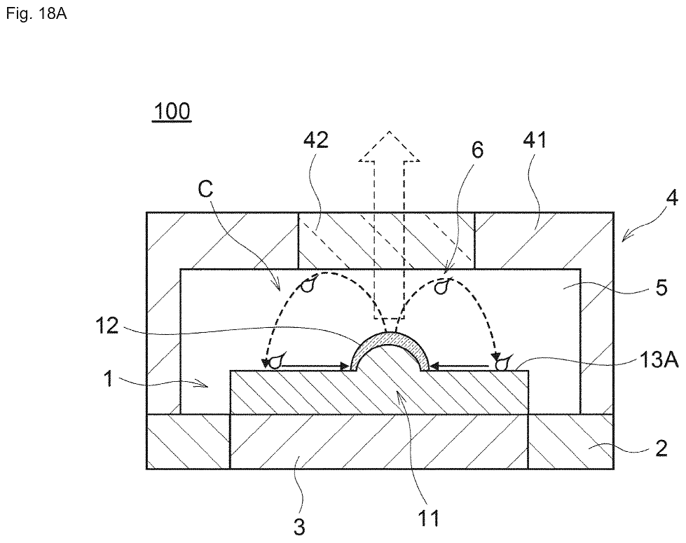

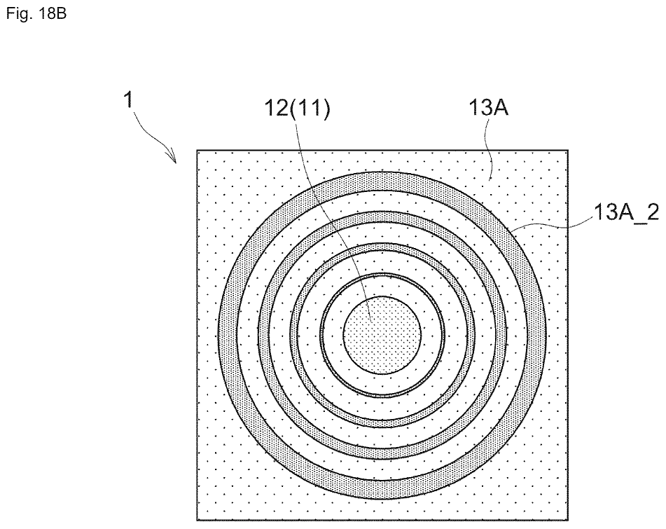

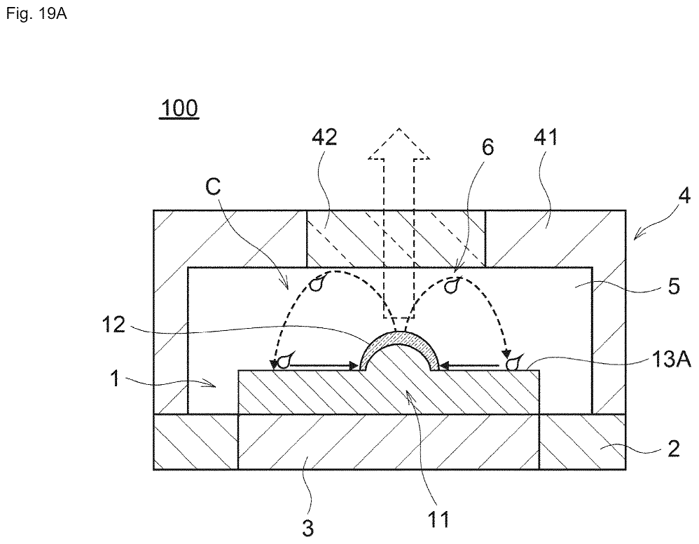

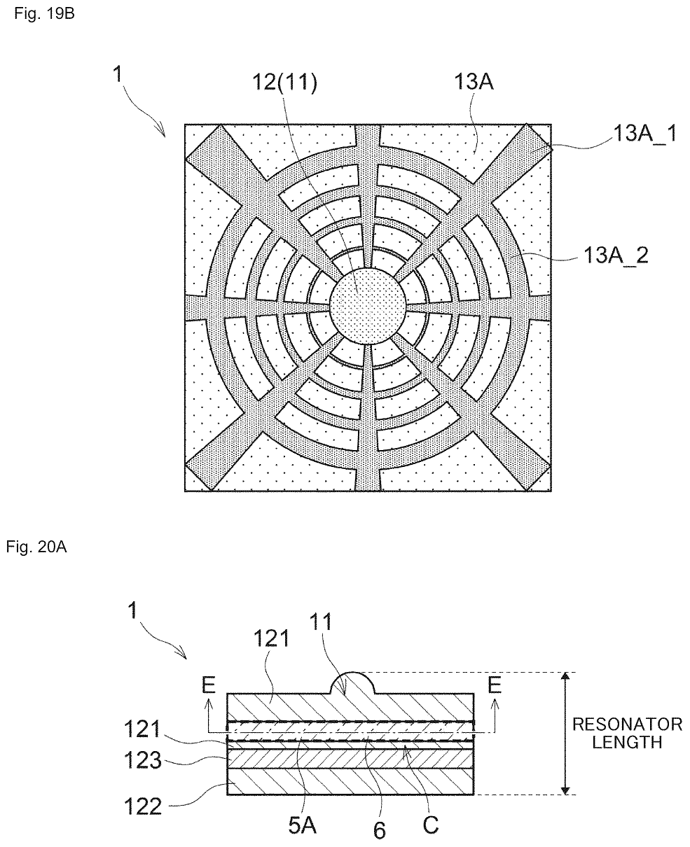

FIG. 18A is a cross-sectional view illustrating a configuration of a semiconductor light emitting device according to the sixteenth embodiment. FIG. 18B is a plan view illustrating a configuration of a semiconductor chip in FIG. 18A. The semiconductor light emitting device 100 according to the present embodiment includes the semiconductor chip 1 that includes the light emitting unit 11, and includes a plurality of grooves 13A_2 around the light emitting unit 11. The plurality of grooves 13A_2 are concentrically disposed on the one major surface of the first region 13A of the semiconductor chip 1. Each of the plurality of grooves 13A_2 each having a different diameter is disposed around the light emitting unit 11 so as to surround the light emitting unit 11. The widths of the plurality of grooves 13A_2 may be wider on the farther side than on the closer side to the light emitting unit 11. Thus, the heat control member C according to the present embodiment includes the plurality of grooves 13A_2. According to such a configuration, the cooling fluid 6 condensed on the one major surface of the first region 13A is caused to flow toward the light emitting unit 11 side using the capillary action in the plurality of grooves 13A_2, so that it is possible to circulate the cooling fluid 6 and efficiently cool the light emitting unit 11.

### Seventeenth Embodiment

FIG. 19A is a cross-sectional view illustrating a configuration of a semiconductor light emitting device according to the seventeenth embodiment. FIG. 19B is a plan view illustrating a configuration of a semiconductor chip in FIG. 19A. The semiconductor chip 1 according to the present embodiment includes the plurality of grooves 13A_1 that are similar to those of the fifteenth embodiment and radially extend, and a plurality of concentric grooves 13A_2 that surround the light emitting unit similarly to the sixteenth embodiment. According to such a configuration, it is possible to obtain the same effect as those of these embodiments.

### Eighteenth Embodiment

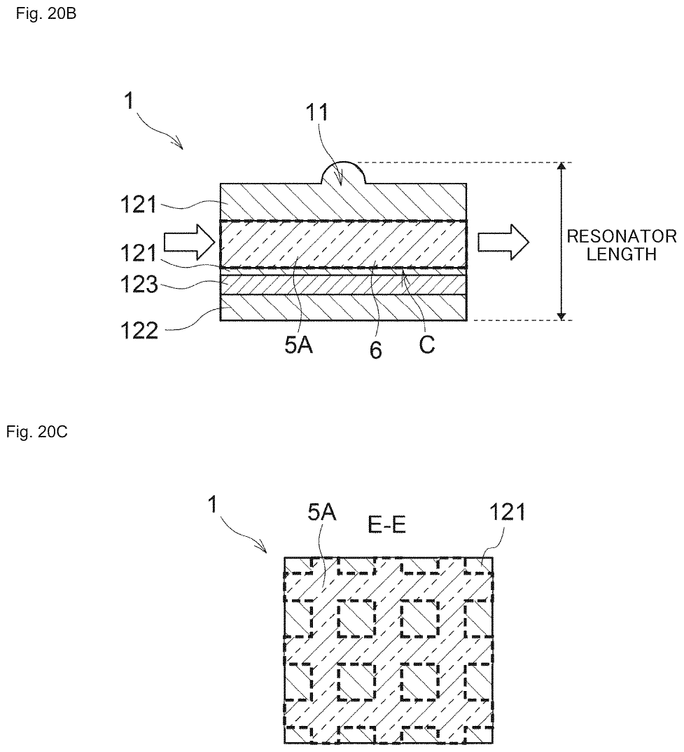

FIG. 20A is a cross-sectional view illustrating a configuration of a semiconductor light emitting device according to the eighteenth embodiment. FIG. 20B is a cross-sectional view for describing a function of a semiconductor chip in FIG. 20A. FIG. 20C is a plan view illustrating the configuration of the semiconductor light emitting device in FIG. 20A. FIG. 20C illustrates a cross-section along a line E-E in FIG. 20A. The light emitting unit 11 according to the present embodiment includes the first compound semiconductor layer 121 that is formed as the n-GaN layer, the active layer 123 that is formed as the five-fold multiple quantum well structure, and the second compound semiconductor layer 122 that is formed as the p-GaN layer as a plurality of stacked layers (see FIG. 3). The heat control member C according to the present embodiment includes a flow passage 5A that is disposed in part of layers of the plurality of layers 121, 122, and 123 and through which the cooling fluid 6 flows. For example, according to the configuration illustrated in FIG. 20A, the flow passage 5A is disposed in the first compound semiconductor layer 121.

In a manufacturing process of the flow passage 5A, the first compound semiconductor layer 121 of n-GaN is epitaxially grown, and then SiO2 is patterned in a shape (lattice pattern) of the flow passage 5A illustrated in FIG. 20C. Next, the first compound semiconductor layer 121 is epitaxially grown again on SiO2. Next, the active layer 123 and the second compound semiconductor layer 122 of p-GaN are epitaxially grown, and then SiO2 of the lattice pattern is removed by a hydrofluoric acid-based drug solution. According to the above-described process, the flow passage 5A is formed in the first compound semiconductor layer 121.

The thickness of the first compound semiconductor layer 121 including the flow passage 5A is adjusted according to the pressure of the cooling fluid 6 flowing in the flow passage 5A. Here, although the light emitting unit 11 includes a resonator that includes the first light reflection layer 141 and the second light reflection layer 142 illustrated in FIG. 3 and oscillates laser light, the resonator length of the light emitted from the light emitting unit 11 according to the present embodiment changes according to the thickness of the first compound semiconductor layer 121. Note that the cooling fluid 6 may be poured from grooves provided on an upper surface side or a lower surface side of the first compound semiconductor layer 121, and may be poured from a side surface side.

According to such a configuration, it is possible to cause the cooling fluid 6 to flow in the flow passage 5A, and cool the light emitting unit 11 of the semiconductor chip 1. Further, by adjusting a flow rate (pressure) of the cooling fluid 6 to be flown in the flow passage 5A, it is possible to control a distance between the first light reflection layer 141 and the second light reflection layer 142 disposed sandwiching the first compound semiconductor layer 121 and the second compound semiconductor layer 122. Consequently, it is possible to control the resonator length of the semiconductor chip 1 corresponding to this distance, and control the wavelength of laser light to be emitted. Further, since light is also reflected by the surfaces that face inside of the first compound semiconductor layer 121 and constitute the flow passage 5A, the reflected wavelength is not emitted from the front surface 12 of the light emitting unit 11. Consequently, it is possible to filter an unnecessary wavelength, and stabilize a longitudinal mode of the laser light to be emitted.

### Nineteenth Embodiment

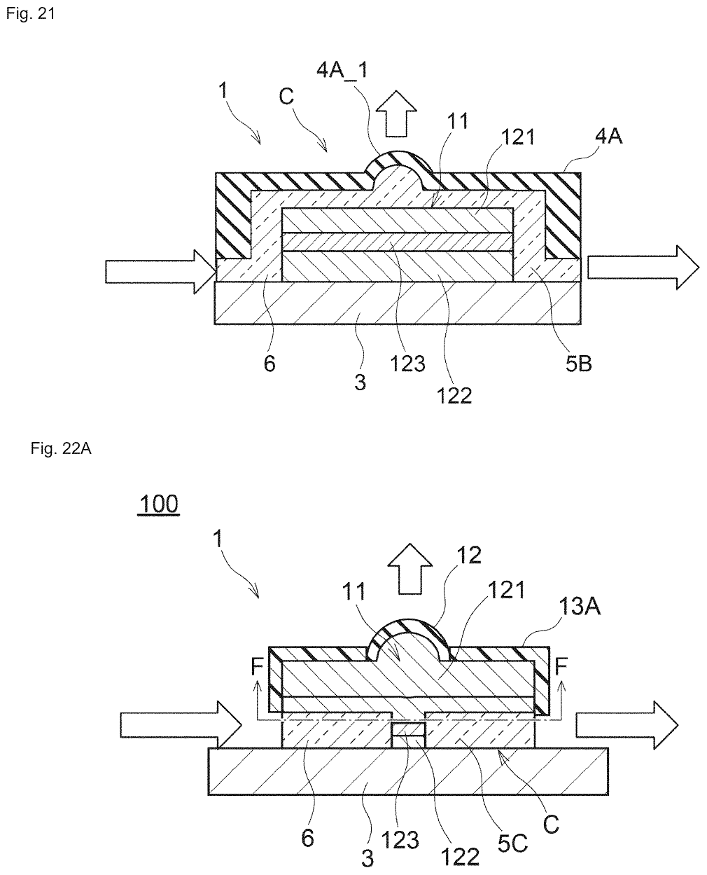

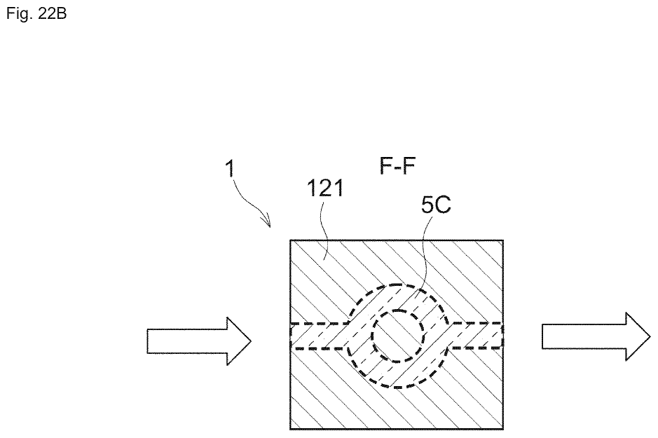

FIG. 21 is a cross-sectional view illustrating a configuration of a semiconductor light emitting device according to the nineteenth embodiment. The heat control member C according to the present embodiment includes a light control member 4A. The light control member 4A covers at least part of the front surface 12 of the light emitting unit 11, and includes a flow passage 5B through which the cooling fluid 6 flows. More specifically, the light control member 4A illustrated in FIG. 21 is formed covering the entire semiconductor chip 1 such that a gap between the semiconductor chip 1 and the light control member 4A constitutes the flow passage 5B. When the cooling fluid 6 flows in the flow passage 5B, it is possible to cause the cooling fluid 6 to flow to the front surface of the light emitting unit 11, and efficiently cool the light emitting unit 11.

Further, the light control member 4A protrudes so as to include a convex lens 4A_1 at a position that overlaps the light emitting unit 11. Consequently, the light control member 4A also functions a collimating lens for light emitted from the light emitting unit 11, and the convex lens 4A_1 can collimate and emit laser light.

### Twentieth Embodiment

FIG. 22A is a cross-sectional view illustrating a configuration of a semiconductor light emitting device according to the twentieth embodiment. FIG. 22B is a plan view illustrating a configuration of a semiconductor light emitting device in FIG. 22A. FIG. 22B illustrates a cross-section along a line F-F in FIG. 22A. The semiconductor chip 1 according to the present embodiment is provided along the first compound semiconductor layer 121, the active layer 123, and the second compound semiconductor layer 122, and includes a flow passage 5C through which the cooling fluid 6 flows as illustrated in FIG. 22B. By causing the cooling fluid 6 to flow in the flow passage 5C, it is possible to cool the light emitting unit 11. Further, the areas of these layers 121, 122, and 123 are narrowed by the flow passage 5C to form the current constriction regions 121, 122, and 123 in which passing ranges of currents from electrodes of the light emitting unit 11 are restricted.

### Twenty First Embodiment

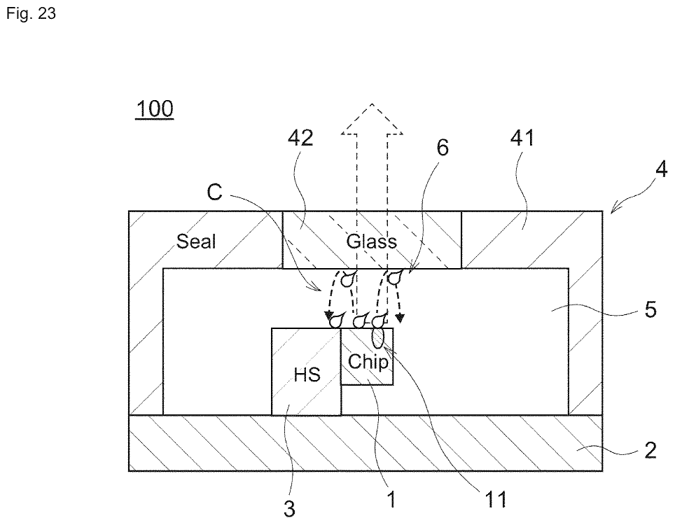

FIG. 23 is a cross-sectional view illustrating a configuration of a semiconductor light emitting device according to the twenty first embodiment. As illustrated in FIG. 23, the semiconductor chip 1 may be an Edge Emitting Laser (EEL) instead of the vertical cavity surface emitting laser. In this case, the semiconductor chip 1 is fixed to the side surface of the heat sink 3 provided vertically with respect to the support substrate 2. According to such a configuration, it is also possible to circulate the cooling fluid 6 heated by the light emitting unit 11 in the space 5 in the sealing member 4, and efficiently cool the light emitting unit 11.

### Twenty Second Embodiment

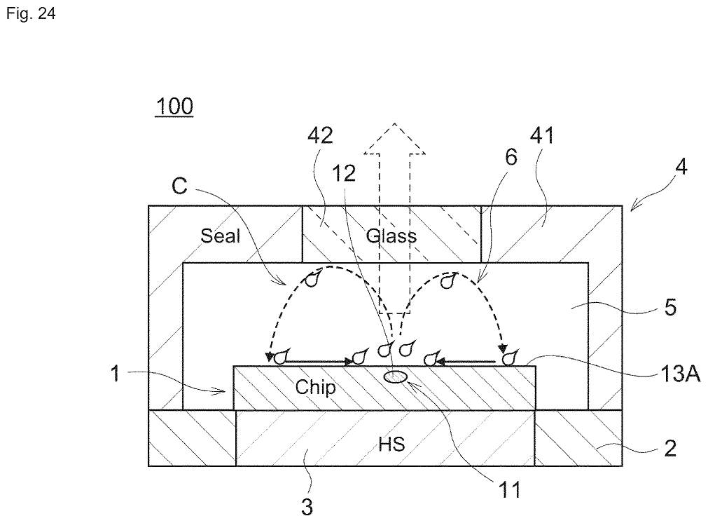

FIG. 24 is a cross-sectional view illustrating a configuration of a semiconductor light emitting device according to the twenty second embodiment. As illustrated in FIG. 24, the semiconductor chip 1 may be a surface emitting laser that includes a reflection layer that is not the concave mirror. In this case, the front surface 12 of the light emitting unit 11 is flat. According to such a configuration, by providing the heat control member C according to the above-described embodiments, it is also possible to circulate the cooling fluid 6 heated by the light emitting unit 11 in the space 5 in the sealing member 4, and efficiently cool the light emitting unit 11.

### Application Examples

The technique according to the present disclosure can be applied to various products. For example, the technique according to the present disclosure may be implemented as an apparatus mounted on any kind of mobile body such as an automobile, an electric vehicle, a hybrid electric vehicle, a motorcycle, a bicycle, a personal mobility, an airplane, a drone, a ship, a robot, a construction machine, or an agricultural machine (tractor).

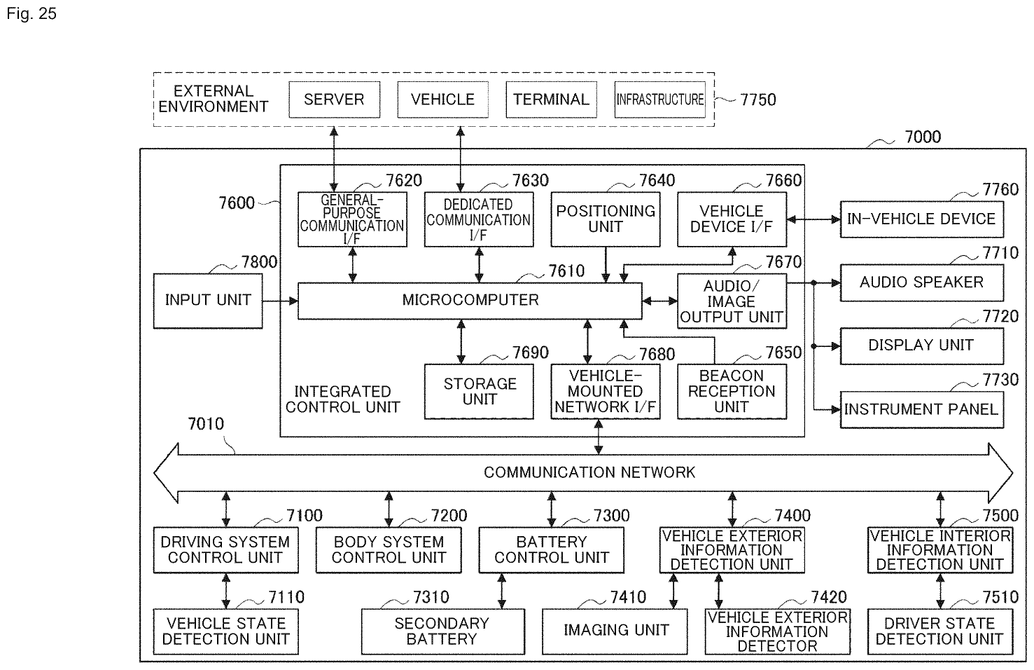

FIG. 25 is a block diagram illustrating a schematic configuration example of a vehicle control system 7000 that is an example of a mobile body control system to which the technique according to the present disclosure is applicable. The vehicle control system 7000 includes a plurality of electronic control units connected via a communication network 7010. In the example illustrated in FIG. 25, the vehicle control system 7000 includes a driving system control unit 7100, a body system control unit 7200, a battery control unit 7300, a vehicle exterior information detection unit 7400, a vehicle interior information detection unit 7500, and an integrated control unit 7600. The communication network 7010 connecting the plurality of control units may be, for example, an in-vehicle communication network compliant with any standards such as CAN (Controller Area Network), LIN (Local Interconnect Network), LAN (Local Area Network), and FlexRay (registered trademark).

Each control unit includes a microcomputer that performs arithmetic processing according to various programs, a storage unit that stores programs executed by the microcomputer, parameters used for various arithmetic operations, and the like, and a drive circuit that drives various control target devices. Each control unit includes a network I/F for performing communication with other control units via the communication network 7010, and includes a communication I/F for performing communication through wired communication or wireless communication with devices, sensors, or the like inside or outside of the vehicle. In FIG. 25, a microcomputer 7610, a general-purpose communication I/F 7620, a dedicated communication I/F 7630, a positioning unit 7640, a beacon reception unit 7650, an in-vehicle device I/F 7660, an audio/image output unit 7670, a vehicle-mounted network I/F 7680, and a storage unit 7690 are illustrated as functional configurations of the integrated control unit 7600. The other control units also include a microcomputer, a communication I/F, a storage unit, and the like.

The driving system control unit 7100 controls the operations of devices related to the drive system of the vehicle according to various programs. For example, the driving system control unit 7100 functions as a control device for a driving force generation device for generating a vehicle driving force of an internal combustion engine or a drive motor, a driving force transmission mechanism for transmitting the driving force to wheels, a steering mechanism for adjusting a steering angle of the vehicle, a braking device that generates a braking force of the vehicle. The driving system control unit 7100 may have a function as a control device, for example, an ABS (Antilock Brake System) or ESC (Electronic Stability Control).

A vehicle state detection unit 7110 is connected to the driving system control unit 7100. The vehicle state detection unit 7110 includes, for example, at least one of a gyro sensor that detects an angular velocity of an axial rotation motion of a vehicle body, an acceleration sensor that detects an acceleration of a vehicle, and sensors for detecting an amount of operation with respect to an accelerator pedal, an amount of operation with respect to a brake pedal, a steering angle of a steering wheel, an engine speed, a rotation speed of wheels, and the like. The driving system control unit 7100 performs arithmetic processing using a signal input from the vehicle state detection unit 7110 to control an internal combustion engine, a drive motor, an electric power steering device, a brake device, and the like.

The body system control unit 7200 controls operations of various devices equipped in the vehicle body in accordance with various programs. For example, the body system control unit 7200 functions as a control device of a keyless entry system, a smart key system, a power window device, or various lamps such as a head lamp, a back lamp, a brake lamp, a turn indicator, and a fog lamp. In this case, radio waves emitted from a portable device in place of a key or signals of various switches can be input to the body system control unit 7200. The body system control unit 7200 receives inputs of radio waves or signals and controls a door lock device, a power window device, and a lamp of the vehicle.

The battery control unit 7300 controls a secondary battery 7310 that is a power supply source of a driving motor in accordance with various programs. For example, information such as a battery temperature, a battery output voltage, or a remaining capacity of a battery is input from a battery device including the secondary battery 7310 to the battery control unit 7300. The battery control unit 7300 performs arithmetic processing using such a signal and performs temperature adjustment control of the secondary battery 7310 or control of a cooling device equipped in the battery device.

The vehicle exterior information detection unit 7400 detects information outside of the vehicle in which the vehicle control system 7000 is mounted. For example, at least one of an imaging unit 7410 and a vehicle exterior information detector 7420 is connected to the vehicle exterior information detection unit 7400. The imaging unit 7410 includes at least one of a ToF (Time Of Flight) camera, a stereo camera, a monocular camera, an infrared camera, and other cameras. The vehicle exterior information detector 7420 includes at least one of, for example, an environmental sensor for detecting a current weather or atmospheric phenomenon and a surrounding information detection sensor for detecting other vehicles, obstacles, or pedestrians or the like around the vehicle in which the vehicle control system 7000 is mounted.

The environmental sensor may be, for example, at least one of a raindrop sensor that detects rainy weather, a fog sensor that detects fog, a sunshine sensor that detects the degree of sunshine, and a snow sensor that detects snowfall. The surrounding information detection sensor may be at least one of an ultrasonic sensor, a radar device, and a LIDAR (Light Detection and Ranging, Laser Imaging Detection and Ranging) device. The imaging unit 7410 and the vehicle exterior information detector 7420 may be provided as independent sensors or devices or may be provided as a device in which a plurality of sensors or devices are integrated.

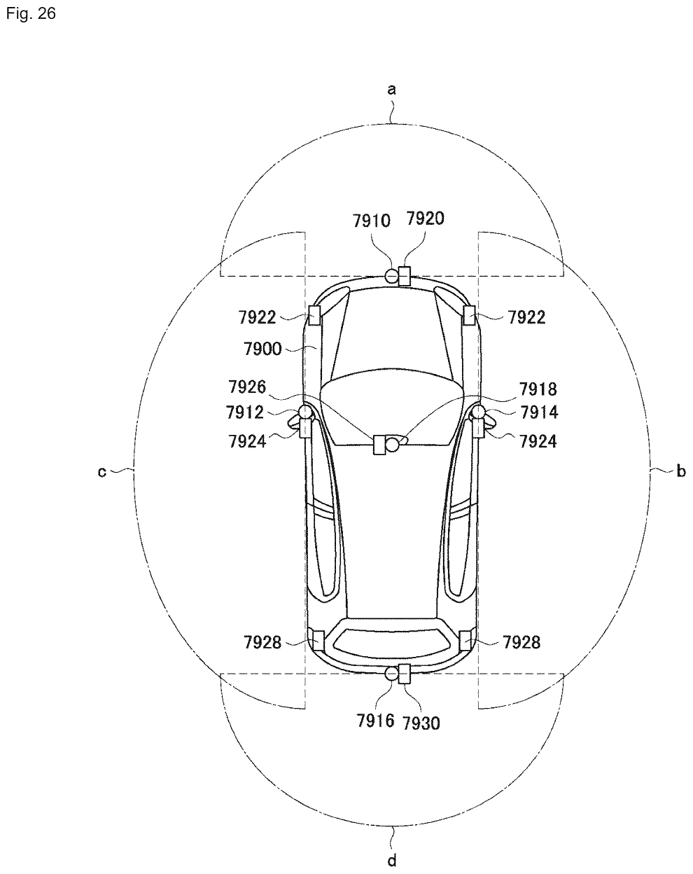

Here, FIG. 26 illustrates an example of installation positions of the imaging unit 7410 and the vehicle exterior information detector 7420. Imaging units 7910, 7912, 7914, 7916, and 7918 are provided, for example, at at least one of a front nose, side mirrors, a rear bumper, a back door, and an upper part of a windshield in a vehicle cabin of the vehicle 7900. The imaging unit 7910 included in the front nose and the imaging unit 7918 included in the upper part of the windshield in the vehicle cabin mainly acquire an image in front of the vehicle 7900. The imaging units 7912 and 7914 included in the side mirrors mainly acquire images of the sides of the vehicle 7900. The imaging unit 7916 included in the rear bumper or the back door mainly acquires an image of the rear of the vehicle 7900. The imaging unit 7918 included in the upper part of the windshield in the vehicle cabin is mainly used for detection of a preceding vehicle, a pedestrian, an obstacle, a traffic light, a traffic sign, a lane, or the like.

In FIG. 26, an example of shooting ranges of the respective imaging units 7910, 7912, 7914, and 7916 is illustrated. An imaging range a indicates an imaging range of the imaging unit 7910 provided on the front nose, imaging ranges b and c indicate imaging ranges of the imaging units 7912 and 7914 provided on the side mirrors, and an imaging range d indicates an imaging range of the imaging unit 7916 provided on the rear bumper or the back door. For example, a bird's-eye view image of the vehicle 7900 as viewed from above can be obtained when the image data captured by the imaging units 7910, 7912, 7914, and 7916 are superimposed.

Vehicle exterior information detectors 7920, 7922, 7924, 7926, 7928, and 7930 provided in a front, a rear, a side, a corner, and an upper part of the windshield in the vehicle cabin of the vehicle 7900 may be, for example, ultrasonic sensors or radar devices. The vehicle exterior information detectors 7920, 7926, and 7930 provided at the front nose, the rear bumper, the back door, and the upper part of the windshield in the vehicle cabin of the vehicle 7900 may be, for example, LIDAR devices. These vehicle exterior information detectors 7920 to 7930 are mainly used for detection of a preceding vehicle, a pedestrian, an obstacle, or the like.

The description will be continued with reference to FIG. 25 again. The vehicle exterior information detection unit 7400 causes the imaging unit 7410 to capture an image of the outside of the vehicle and receives the captured image data. Further, the vehicle exterior information detection unit 7400 receives detection information from the connected vehicle exterior information detector 7420. When the vehicle exterior information detector 7420 is an ultrasonic sensor, a radar device, or a LIDAR device, the vehicle exterior information detection unit 7400 transmits ultrasonic waves, electromagnetic waves, or the like, and receives information on received reflected waves. The vehicle exterior information detection unit 7400 may perform object detection processing or distance detection processing for a person, a vehicle, an obstacle, a sign, a character on a road surface, or the like on the basis of the received information. The vehicle exterior information detection unit 7400 may perform environment recognition processing for recognizing rainfall, fog, road surface situation, and the like on the basis of the received information. The vehicle exterior information detection unit 7400 may calculate a distance to an object outside of the vehicle on the basis of the received information.

Further, the vehicle exterior information detection unit 7400 may perform image recognition processing or distance detection processing for recognizing a person, a vehicle, an obstacle, a sign, a character on a road surface, or the like on the basis of the received image data. The vehicle exterior information detection unit 7400 may perform processing such as distortion correction or alignment on the received image data, and combine image data captured by the different imaging units 7410 to generate a bird's-eye view image or a panoramic image. The vehicle exterior information detection unit 7400 may perform viewpoint conversion processing using the image data captured by the different imaging units 7410.

The vehicle interior information detection unit 7500 detects information inside of the vehicle. For example, a driver state detection unit 7510 that detects a driver's state is connected to the vehicle interior information detection unit 7500. The driver state detection unit 7510 may include a camera that images a driver, a biological sensor that detects biological information of the driver, or a microphone that collects a sound in the vehicle cabin. The biological sensor is provided on, for example, a seat surface, a steering wheel, or the like and detects biological information of an occupant sitting on the seat or the driver holding the steering wheel. The vehicle interior information detection unit 7500 may calculate the degree of fatigue or the degree of concentration of the driver or determine whether the driver is drowsing based on detected information input from the driver state detection unit 7510. The vehicle interior information detection unit 7500 may perform a noise cancellation process or the like on a collected sound signal.

The integrated control unit 7600 controls overall operations in the vehicle control system 7000 according to various programs. An input unit 7800 is connected to the integrated control unit 7600. The input unit 7800 is implemented by a device that can be operated for input by a passenger, for example, a touch panel, a button, a microphone, a switch, or a lever. Data obtained by recognizing voice inputted through a microphone may be inputted to the integrated control unit 7600. The input unit 7800 may be, for example, a remote control device using infrared rays or other radio waves, or may be an externally connected device such as a mobile phone or a PDA (Personal Digital Assistant) corresponding to an operation on the vehicle control system 7000. The input unit 7800 may be, for example, a camera. In this case, the passenger can input information by gesture. Alternatively, data obtained by detecting a motion of a wearable device worn by the passenger may be input. Further, the input unit 7800 may include, for example, an input control circuit that generates an input signal on the basis of information input by the passenger or the like using the input unit 7800 and outputs the input signal to the integrated control unit 7600. The passenger or the like inputs various types of data to the vehicle control system 7000 or instructs a processing operation by operating the input unit 7800.

The storage unit 7690 may include a ROM (Read Only Memory) that stores various programs to be executed by a microcomputer, and a RAM (Random Access Memory) that stores various parameters, calculation results, or sensor values or the like. The storage unit 7690 may be implemented by, for example, a magnetic storage device such as an HDD (Hard Disc Drive), a semiconductor storage device, an optical storage device, or a magneto-optical storage device.

The general-purpose communication I/F 7620 is a general-purpose communication I/F that mediates communication with various devices present in an external environment 7750. The general-purpose communication I/F 7620 may have, implemented therein, a cellular communication protocol such as GSM (Global System of Mobile communications) (registered trademark), WiMAX (registered trademark), LTE (Long Term Evolution) (registered trademark), or LTE-A (LTE-Advanced), or other wireless communication protocols such as wireless LAN (also referred to as Wi-Fi (registered trademark)) or Bluetooth (registered trademark). The general-purpose communication I/F 7620 may be connected to, for example, a device (for example, an application server or a control server) present on an external network (for example, the Internet, a cloud network, or a business-specific network) via a base station or an access point. The general-purpose communication I/F 7620 may be connected to terminals (for example, the terminals of the driver, pedestrians, or shops, or MTC (Machine Type Communication) terminals) near the vehicle by using, for example, P2P (Peer To Peer) technology.

The dedicated communication I/F 7630 is a communication I/F supporting a communication protocol formulated for the purpose of use in a vehicle. The dedicated communication I/F 7630 may implement, for example, a standard protocol such as a WAVE (Wireless Access in Vehicle Environment) that is a combination of IEEE802.11p of a lower layer and IEEE1609 of an upper layer, a DSRC (Dedicated Short Range Communications), or a cellular communication protocol. The dedicated communication I/F 7630 typically performs V2X communications as a concept including one or more of vehicle to vehicle communications, vehicle to infrastructure communications, vehicle to home communications, and vehicle to pedestrian communications.

The positioning unit 7640 receives, for example, a GNSS signal from a global navigation satellite system (GNSS) satellite (for example, a GPS signal from a global positioning system (GPS) satellite), executes positioning, and generates position information including a latitude, longitude, and altitude of the vehicle. The positioning unit 7640 may specify a current position by exchanging signals with a wireless access point, or may acquire position information from a terminal such as a mobile phone, PHS, or smartphone having a positioning function.

The beacon reception unit 7650 receives radio waves or electromagnetic waves transmitted from a radio station or the like installed on a road, and acquires information such as a current position, traffic jam, no throughfare, or required time. A function of the beacon reception unit 7650 may be included in the above-described dedicated communication I/F 7630.

The in-vehicle device I/F 7660 is a communication interface that mediates connections between the microcomputer 7610 and various in-vehicle devices 7760 present in the vehicle. The in-vehicle device I/F 7660 may establish a wireless connection using wireless communication protocols such as a wireless LAN, Bluetooth (registered trademark), NFC (Near Field Communication), and WUSB (Wireless USB). Furthermore, the in-vehicle device I/F 7660 may establish a wired connection of, for example, a USB (Universal Serial Bus), HDMI (registered trademark) (High-Definition Multimedia Interface), or MHL (Mobile High-definition Link) via a connection terminal (not illustrated) (and a cable if necessary). The in-vehicle device 7760 may include, for example, at least one of a mobile device or a wearable device of a passenger and an information device carried in or attached to the vehicle. Further, the in-vehicle device 7760 may include a navigation device that searches for a route to an arbitrary destination. The in-vehicle device I/F 7660 exchanges control signals or data signals with the in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various programs based on information acquired through at least one of the general-purpose communication I/F 7620, the dedicated communication I/F 7630, the positioning unit 7640, the beacon reception unit 7650, the in-vehicle device I/F 7660, and the vehicle-mounted network I/F 7680. For example, the microcomputer 7610 may calculate control target values for a driving force generation device, a steering mechanism, or a braking device on the basis of acquired information on the inside and outside of the vehicle, and output control commands to the driving system control unit 7100. For example, the microcomputer 7610 may perform cooperative control for the purpose of implementing the functions of ADAS (Advanced Driver Assistance System), the functions including vehicle collision avoidance or impact mitigation, follow-up traveling based on an inter-vehicle distance, vehicle speed maintenance driving, a vehicle collision warning, and a vehicle lane departure warning. The microcomputer 7610 may perform coordinated control for automated driving in which a vehicle travels autonomously regardless of an operation of a driver, by controlling, for example, a driving force generation device, a steering mechanism, or a braking device on the basis of acquired surrounding information on the vehicle.

The microcomputer 7610 may generate 3-dimensional distance information between the vehicle and objects such as surrounding structures or people based on information acquired via at least one of the general-purpose communication I/F 7620, the dedicated communication I/F 7630, the positioning unit 7640, the beacon reception unit 7650, the in-vehicle device I/F 7660, and the vehicle-mounted network I/F 7680 and may generate local map information including surrounding information of a present position of the vehicle. The microcomputer 7610 may predict a danger such as collision of the vehicle, approach of a pedestrian, or entry into a traffic prohibition road based on the acquired information and may generate a warning signal. The warning signal may be, for example, a signal for generating a warning sound or turning on a warning lamp.

The audio/image output unit 7670 transmits at least one of audio and image output signals to an output device capable of visually or audibly notifying a passenger of the vehicle or the outside of the vehicle of information. In the example of FIG. 25, an audio speaker 7710, a display unit 7720, and an instrument panel 7730 are illustrated as output devices. The display unit 7720 may include, for example, at least one of an on-board display and a head-up display. The display unit 7720 may have an AR (Augmented Reality) display function. The output device may be other devices such as a headphone, a wearable device such as a glasses-type display worn by a passenger, a projector, and a lamp. When the output device is a display device, the display device visually displays results obtained through various processes performed by the microcomputer 7610 or information received from another control unit in various formats such as text, images, tables, and graphs. When the output device is a sound output device, the sound output device converts an audio signal formed by reproduced sound data, acoustic data, or the like into an analog signal and outputs the analog signal auditorily.

In the example illustrated in FIG. 25, at least two control units connected via the communication network 7010 may be integrated as one control unit. Alternatively, each control unit may be configured of a plurality of control units. Further, the vehicle control system 7000 may include another control unit (not illustrated). Further, in the above description, the other control unit may have some or all of functions of any one of the control units. That is, predetermined calculation processing may be performed by any one of the control units as long as information is transmitted and received via the communication network 7010. Similarly, a sensor or device connected to any one of the control units may be connected to the other control unit, and a plurality of control units may transmit or receive detection information to and from each other via the communication network 7010.

In the vehicle control system 7000 described above, the semiconductor light emitting device according to the present embodiment described with reference to FIG. 1 and the like can be applied to the vehicle exterior information detector 7420 of the application example illustrated in FIG. 25.

The present technique can also employ the following configurations.

(1) A semiconductor light emitting device including:

a light emitting unit;

a sealing member that includes a transmission part that allows light emitted from the light emitting unit to transmit; and

a heat control member that disperses heat of the light emitting unit using a cooling fluid inside of the sealing member.

(2) In the semiconductor light emitting device described in (1), the heat control member causes the heat of the light emitting unit using the cooling fluid to convect between the light emitting unit and the sealing member.

(3) In the semiconductor light emitting device described in (1) or (2), the cooling fluid is a gas, a liquid, or a solid that takes in the heat, and evaporates, melts, or sublimes.

(4) In the semiconductor light emitting device described in any one of (1) to (3), the heat control member includes a first region that is disposed around the light emitting unit and has higher wettability than wettability of a front surface of the light emitting unit.

(5) In the semiconductor light emitting device described in any one of (1) to (3), the heat control member includes a first region that is disposed around the light emitting unit, and has at least one of a surface tension and surface roughness different from a surface tension and surface roughness of a front surface of the light emitting unit.

(6) In the semiconductor light emitting device described in (4) or (5), the heat control member includes a second region that is disposed on the front surface of the light emitting unit, and has higher water repellency or oil repellency than water repellency or oil repellency of the first region.

(7) In the semiconductor light emitting device described in (6), the heat control member includes a plurality of protrusion parts provided on the front surface of the light emitting unit.

(8) In the semiconductor light emitting device described in any one of (1) to (3), the heat control member includes

a first region that is disposed around the light emitting unit, and

a second region that is disposed on a front surface of the light emitting unit, and whose temperature becomes higher than a temperature of the first region at a time of light emission of the light emitting unit.

(9) In the semiconductor light emitting device described in (8), the second region is disposed on a side closer to the transmission part than the first region, and the heat control member causes convection of the heat inside of the sealing member according to a temperature difference between the first region and the second region.

(10) In the semiconductor light emitting device described in any one of (1) to (9), the light emitting unit includes a protrusion part that has an upper surface on which a light emission surface is disposed, and

the heat control member includes a roughened region that is disposed on at least part of a side surface of the protrusion part.

(11) In the semiconductor light emitting device described in any one of (1) to (10), at least part of an inner surface of the sealing member is a curved shape.

(12) The semiconductor light emitting device described in any one of (1) to (11) includes a semiconductor chip that includes the light emitting unit,

the heat control member includes a plurality of grooves that are disposed on one major surface of the semiconductor chip,

each of the plurality of grooves radially extends from the light emitting unit to an end part of the one major surface, and

widths of the plurality of grooves are wider on a farther side than on a closer side to the light emitting unit.

(13) The semiconductor light emitting device described in any one of (1) to (11) includes a semiconductor chip that includes the light emitting unit,

the heat control member includes a plurality of grooves that are disposed on one major surface of the semiconductor chip,

each of the plurality of grooves each having a different diameter is disposed around the center of the light emitting unit so as to surround the light emitting unit, and

widths of the plurality of grooves are wider on a farther side than on a closer side to the light emitting unit.

(14) In the semiconductor light emitting device described in any one of (1) to (13), the light emitting unit includes a plurality of stacked layers, and

the heat control member includes a flow passage that is disposed in part of layers of the plurality of layers and through which the cooling fluid flows.

(15) In the semiconductor light emitting device described in (14), thicknesses of the part of layers are variably adjusted according to a pressure of the cooling fluid flowing in the flow passage,

the light emitting unit includes a resonator that resonates the light, and a resonator length of the light emitted from the light emitting unit changes according to the thicknesses of the part of layers.

(16) In the semiconductor light emitting device described in (14) or (15), the part of layers includes a current constriction region whose passing range of a current from an electrode of the light emitting unit is restricted by the flow passage.

(17) In the semiconductor light emitting device described in any one of (1) to (16), the heat control member includes a light control member that covers at least part of the front surface of the light emitting unit, and includes a flow passage through which the cooling fluid flows.

(18) In the semiconductor light emitting device described in (17), the light control member has a front surface shape that can collimate the light emitted from the light emitting unit and emit the light.

(19) The semiconductor light emitting device described in any one of (1) to (18) includes a concave mirror that is disposed on a front surface of the light emitting unit, and

the light emitting unit is a surface emitting laser that reflects light from an active layer by the concave mirror, or a vertical cavity surface emitting laser.

(20) The semiconductor light emitting device described in any one of (1) to (19) further includes an array part that includes a plurality of the light emitting units disposed in a one-dimensional or two-dimensional direction,

the sealing member seals the array part and allows light emitted from each of the plurality of the light emitting units to transmit from the transmission part, and the heat control member disperses heat of the plurality of light emitting units using the cooling fluid inside of the sealing member.

Aspects of the present disclosure are not limited to the aforementioned individual embodiments and include various modifications that those skilled in the art can achieve, and effects of the present disclosure are also not limited to the details described above. In other words, various additions, modifications, and partial deletion can be made without departing from the conceptual idea and the gist of the present disclosure that can be derived from the details defined in the claims and the equivalents thereof.

### Reference Signs List

1 Semiconductor chip
2 Support substrate
3 Heat sink
4 Sealing member
41, 41A Cap
42 Transmission part
4A Light control member
4A_1 Convex lens
5 Space
5A to 5C Flow passage
6 Cooling fluid
11 Light emitting unit
11A High temperature part 12 Front surface
12A, 12B, 12D Second region
12A_1 Convex part
12C Convex part
12C_1 Roughened region
13A, 13B, 13C, 13D First region
13A One major surface
13A_1, 13A_2 Plurality of grooves
14 Array part
100 Semiconductor light emitting device
121 First compound semiconductor layer (current constriction region)
122 Second compound semiconductor layer (current constriction region)
123 Active layer (current constriction region)
C Heat control member _{Y}c Surface tension (critical surface tension)

1. A semiconductor light emitting device comprising:
a light emitting unit;
a sealing member that includes a transmission part that allows light emitted from the light emitting unit to transmit; and
a heat control member that disperses heat of the light emitting unit using a cooling fluid inside of the sealing member.

2. The semiconductor light emitting device according to claim 1, wherein the heat control member causes the heat of the light emitting unit using the cooling fluid to convect between the light emitting unit and the sealing member.

3. The semiconductor light emitting device according to claim 1, wherein the cooling fluid is a gas, a liquid, or a solid that takes in the heat, and evaporates, melts, or sublimes.

4. The semiconductor light emitting device according to claim 1, wherein the heat control member includes a first region that is disposed around the light emitting unit and has higher wettability than wettability of a front surface of the light emitting unit.

5. The semiconductor light emitting device according to claim 1, wherein the heat control member includes a first region that is disposed around the light emitting unit, and has at least one of a surface tension and surface roughness different from a surface tension and surface roughness of a front surface of the light emitting unit.

6. The semiconductor light emitting device according to claim 4, wherein the heat control member includes a second region that is disposed on the front surface of the light emitting unit, and has higher water repellency or oil repellency than water repellency or oil repellency of the first region.

7. The semiconductor light emitting device according to claim 6, wherein the heat control member includes a plurality of protrusion parts provided on the front surface of the light emitting unit.

8. The semiconductor light emitting device according to claim 1, wherein the heat control member includes
a first region that is disposed around the light emitting unit, and
a second region that is disposed on a front surface of the light emitting unit, and whose temperature becomes higher than a temperature of the first region at a time of light emission of the light emitting unit.

9. The semiconductor light emitting device according to claim 8, wherein
the second region is disposed on a side closer to the transmission part than the first region, and
the heat control member causes convection of the heat inside of the sealing member according to a temperature difference between the first region and the second region.

10. The semiconductor light emitting device according to claim 1, wherein
the light emitting unit includes a protrusion part that has an upper surface on which a light emission surface is disposed, and
the heat control member includes a roughened region that is disposed on at least part of a side surface of the protrusion part.

11. The semiconductor light emitting device according to claim 1, wherein at least part of an inner surface of the sealing member is a curved shape.

12. The semiconductor light emitting device according to claim 1, comprising a semiconductor chip that includes the light emitting unit, wherein
the heat control member includes a plurality of grooves that are disposed on one major surface of the semiconductor chip,
each of the plurality of grooves radially extends from the light emitting unit to an end part of the one major surface, and
widths of the plurality of grooves are wider on a farther side than on a closer side to the light emitting unit.

13. The semiconductor light emitting device according to claim 1, comprising a semiconductor chip that includes the light emitting unit, wherein
the heat control member includes a plurality of grooves that are disposed on one major surface of the semiconductor chip,
each of the plurality of grooves each having a different diameter is disposed around the center of the light emitting unit so as to surround the light emitting unit, and
widths of the plurality of grooves are wider on a farther side than on a closer side to the light emitting unit.

14. The semiconductor light emitting device according to claim 1, wherein
the light emitting unit includes a plurality of stacked layers, and
the heat control member includes a flow passage that is disposed in part of layers of the plurality of layers and through which the cooling fluid flows.

15. The semiconductor light emitting device according to claim 14, wherein
thicknesses of the part of layers are variably adjusted according to a pressure of the cooling fluid flowing in the flow passage,
the light emitting unit includes a resonator that resonates the light, and a resonator length of the light emitted from the light emitting unit changes according to the thicknesses of the part of layers.

16. The semiconductor light emitting device according to claim 14, wherein the part of layers includes a current constriction region whose passing range of a current from an electrode of the light emitting unit is restricted by the flow passage.

17. The semiconductor light emitting device according to claim 1, wherein the heat control member includes a light control member that covers at least part of the front surface of the light emitting unit, and includes a flow passage through which the cooling fluid flows.

18. The semiconductor light emitting device according to claim 17, wherein the light control member has a front surface shape that can collimate the light emitted from the light emitting unit and emit the light.

19. The semiconductor light emitting device according to claim 1, comprising a concave mirror that is disposed on a front surface of the light emitting unit,
wherein the light emitting unit is a surface emitting laser that reflects light from an active layer by the concave mirror, or a vertical cavity surface emitting laser.

20. The semiconductor light emitting device according to claim 1, further comprising an array part that includes a plurality of the light emitting units disposed in a one-dimensional or two-dimensional direction, wherein
the sealing member seals the array part and allows light emitted from each of the plurality of the light emitting units to transmit from the transmission part, and the heat control member disperses heat of the plurality of light emitting units using the cooling fluid inside of the sealing member.
